(19) United States
(12) Patent Application Publication
(10) Pub. No.: US 2010/0044209 A1
(43) Pub. Date: Feb. 25, 2010

(54) HYBRID METAL-SEMICONDUCTOR NANOPARTICLES AND METHODS FOR PHOTO-INDUCING CHARGE SEPARATION AND APPLICATIONS THEREOF

(75) Inventors: Uri Banin, Mevasseret Zion (IL); Ronny Costi, Ashdod (IL)

Correspondence Address: THE NATH LAW GROUP, 112 South West Street, Alexandria, VA, 22314, US

(73) Assignee: YISSUM RESEARCH DEVELOPMENT COMPANY OF THE HEBREW UNIVERISTY OF JERUSALEM, Jerusalem (IL)

(21) Appl. No.: 12/449,642

(22) PCT Filed: Feb. 20, 2008
(86) PCT No.: PCT/IL2008/000220

§ 371 Date: Sep. 10, 2009

Related U.S. Application Data
(60) Provisional application No. 60/902,061, filed on Feb. 20, 2007.

(51) Int. Cl. C01B 3/04

(52) U.S. Cl. 204/157.52; 204/157.15

(57) ABSTRACT

The development and use of hybrid metal-semiconductor nanoparticles for photocatalysis of a variety of chemical reactions such as redox reactions and water-splitting, is provided.

### FIELD OF THE INVENTION

This invention relates generally to hybrid metal-semiconductor nanoparticles, uses thereof in photo-induced charge separation reactions and applications.

### BACKGROUND OF THE INVENTION

Photocatalysis is the acceleration of a photoreaction in the presence of a catalyst. In photo-generated catalysis the photocatalytic activity depends on the ability of a catalyst to absorb light and create electron-hole pairs, which can later enable secondary reduction-oxidation (redox) reactions.

A landmark in photocatalysis is the discovery of water electrolysis by means of a light induced process on titanium dioxide (termed ‘photocatalytic water splitting’) [1]. Photocatalysis has important commercial applications in water splitting and in additional areas including water and air purification, degradation of organic contaminants such as residues from the dye industry [2] and in photoelectrochemical cells [3]. An interesting and promising aspect of this technology is the ability to harness solar energy as the light source for initiating the process. Therefore, photocatalysis also represents an elegant and direct way of harvesting clean and free solar energy, turning it into useful work, for example for generating hydrogen gas from the water-splitting process [4,5], or into useful electrical energy as in the case of in photoelectrochemical cells. Additionally, the photoinduced charge separation process may be directly harnessed to create electrical energy in a photovoltaic (PV) cell. Applications in any of these areas are highly promising and of vast commercial potential and highly important social benefits, as such so-called green-technologies reduce daily dependence on fossil fuels.

The search for efficient photocatalysts has been a long time quest in the field of chemistry and materials science. Semiconductor nanocrystals and nanostructures have been studied for their photocatalytic activity [7,8]. However, due to the rapid recombination of charge carriers in the semiconductor itself, the efficiency of the photocatalytic activity is limited as the charge carriers are not labile for redox reactions.

Addition of metal islands onto semiconducting materials allows the creation of a light induced charge-separated entity, where the semiconductor absorbs the light, creating an electron-hole pair, followed by rapid charge-separation where one type of the charge carriers resides in the metal and the opposite type resides in the semiconductor [9,10]. Such an effect enables the charge carriers to be readily available for chemical and physical processes, such as redox reactions or current flow, and can compete with the undesirable electron-hole recombination process.

Thus far, examples of semiconductor-metal systems for photocatalysis were limited in several aspects; First, most semiconductor photocatalysts were based on high-band gap semiconductors such as TiO₂, ZnO and CdS [11,12,13,14]. The high band gap semiconductor limits severely the applicability of the photocatalyst, as it does not match the solar spectrum. For example, the most common photocatalyst system, TiO₂, can absorb only in the UV, harvesting only 2-4% of the solar spectrum. Even in the case of Bao et al [6], who reported the production of Pt-loaded CdS nanostructures for photocatalytic production of hydrogen under blue light, the band gap of the CdSe nanostructure was limited to wavelengths of 520 nm and below, which limits the range of solar absorption of the photocatalyst. Moreover, only limited control of nanostructure size and shape was achieved and the metal deposition was also with limited control. In fact, the use of catalysts having photodeposited thereon 10% co-catalyst provides no indication as to the structure and shape of the catalysts.

Second, all of the systems developed thus far are not well controlled in terms of the metal islands size, location of the metal on the semiconductor and even in metal type. In fact, the combined semiconductor-metal systems suffer from broad size, shape and even composition distributions. This limits not only the ability to research and understand the performance of the photocatalyst but also the ability to improve it in a controlled manner.

Finally, in all systems used thus far the nanoparticles were either doped in a polymeric matrix or present as a nanostructured film having a non-homogenous nanoparticle size distribution. These structures reduced the chemical processability of the nanoparticles, their homogenous distribution in a liquid/gel medium and their sophisticated use in more complex structures (such as a homogenous self-assembled thin film, or coating of an electrode surface) without altering their properties.

### REFERENCES

[1] Borgarello, E.; Kiwi, J.; Pelizzetti, E.; Visca, M.; Gratzel, M. Nature 1981, 289, (5794), 158-160
[2] Wu, C. H.; Chem, J. M. Industrial & Engineering Chemistry Research 2006, 45, (19), 6450-6457
[3] Gratzel, M. Nature 2001, 414, (6861), 338-344
[4] Baba, R.; Nakabayashi, S.; Fujishima, A.; Honda, K. Journal of Physical Chemistry 1985, 89, (10), 1902-1905
[5] Bard, A. J.; Fox, M. A. Accounts of Chemical Research 1995, 28, (3), 141-145
[6] Bao, N.; Shen, L.; Takat, T.; Lu, D.; Domen, K. Chemistry Letters 2006, 35 (3), 318-319
[7] Chandrasekharan, N.; Kamat, P. V. Journal of Physical Chemistry B 2000, 104, (46), 10851-10857
[8] Subramanian, V.; Wolf, E.; Kamat, P. V. Journal of Physical Chemistry B 2001, 105, (46), 11439-11446
[9] Sykora, M.; Petruska, M. A.; Alstrum-Acevedo, J.; Bezel, I.; Meyer, T. J.; Klimov, V. I. Journal of the American Chemical Society 2006, 128, (31), 9984-9985
[10] Wang, P.; Abrusci, A.; Wong, H. M. P.; Svensson, M.; Andersson, M. R; Greenham, N. C. Nano Letters 2006, 6, (8), 1789-1793
[11] Sharma, K. N.; Barua, K. Journal of Physics D-Applied Physics 1979, 12, (10), 1729-1735
[12] Tada, H.; Mitsui, T.; Kiyonaga, T.; Akita, T.; Tanaka, K. Nature Materials 2006, 5, (10), 782-786
[13] Saunders, A. E.; Popov, I.; Banin, U. Journal of Physical Chemistry B 2006, 110, (50), 25421-25429
[14] Jiang, W.; Mardyani, S.; Fischer, H.; Chan, W. C. W. Chemistry of Materials 2006, 18, (4), 872-878
[15] International Publication No. WO 05/075339
[16] Peng, X. G.; Manna, L.; Yang, W. D.; Wickham, J.; Scher, E.; Kadavanich, A.; Alivisatos, A. P. Nature 2000, 404, (6773), 59-61
[17] Salant, A.; Amitay-Sadovsky, E.; Banin, U. Journal of the American Chemical Society 2006, 128, (31), 10006-10007
[18] Chan, W. C. W.; Nie, S. M. Science 1998, 281, (5385), 2016-2018
[19] Mokari, T.; Rothenberg, E.; Popov, I.; Costi, R.; Banin, U. Science 2004, 304, (5678), 1787-1790
[20] Jiang, W.; Mardyani, S.; Fischer, H.; Chan, W. C. W. Chemistry of Materials 2006, 18, (4), 872-878
[21] Chemiavskaya, O.; Chen, L. W.; Brus, L. Journal of Physical Chemistry B 2004, 108, (16), 4946-4961
[22] Lugo, J. E.; Taguena-Martinez, J.; del Rio, J. A. Solid State Communications 2001, 117, (9), 555-559

### SUMMARY OF THE INVENTION

The present invention concerns the development and use of photocatalysts which are based on highly controlled semiconductor-metal hybrid nanoparticles, exhibiting light induced charge separation effect. This effect was observed in. the single particle as well as in a plurality of such particles. The photocatalysts (nanoparticles) of the invention, or those employed by methods of the invention, were found to have applicability in various photocatalytic reactions and other applications employing light induced charge separation such as electrochemical and photovoltaic cells, particularly in view of the surprising discovery that photocatalysis may be achieved by simply exposing the systems disclosed herein to solar radiation. This leads to the development of a great variety of methods and devices useful in chemical transformations such as those disclosed herein, in particular those associated with the decomposition of environmental contaminants and water splitting.

As will be further detailed hereinbelow, for the nanoparticles to have efficient photocatalytic activity, they must be constructed as hybrid nanoparticles comprising each at least one metal/metal alloy region and at least one semiconductor region having an absorption onset in the visible (400-700 nm) to near infrared (NIR) range (0.7-3 μm). These nanoparticles, which structure is further discussed herein, may generally be characterized as follows:

1. they may be constructed in a variety of shapes and sizes, size distributions and chemical compositions;

2. they have excellent chemical processability via surface treatments as demonstrated for example by the ability to make them soluble in aqueous or organic media, depending on the surface coating;

3. their surface, e.g., surface of the semiconductor and/or metal regions, may be functionalized to allow self-assembly;

4. the photocatalytic effect may be observed in the single as well as in a plurality (population) of photocatalysts;

5. they may retain charge and thus may be used to catalyze chemical reactions even in the dark;

6. they may be constructed into unique nanostructures comprising one or more nanoparticle populations; and

7. they may be used in a variety of devices.

Thus, the present invention provides light-activated hybrid nanoparticles comprising each at least one metal/metal alloy region and at least one semiconductor region having an absorption onset in the visible (400-700 nm) to near infrared (NIR) range (0.7-3 μm), for use as photocatalysts and in the constructions of devices incorporating light-induced charge separation.

In some embodiments, the at least one semiconductor region has an absorption onset in the range of 420 nm to 3 μm.

In some other embodiments, the at least one semiconductor region has an absorption onset in the range of 450 nm to 3 μm.

In further embodiments, the at least one semiconductor region has an absorption onset in the range of 470 nm to 3 μm.

In still other embodiments, the at least one semiconductor region has an absorption onset in the range of 500 nm to 3 μm.

When the nanoparticles employed in photocatalysis, in accordance with the present invention, are irradiated (illuminated) with a light source having an energy exceeding the band gap energy of a semiconductor material of the nanoparticles, electrons and positive holes are formed in the form of an electron-hole pair, e.g., at the metal/semiconductor interface or in certain embodiments at the interface of two contacting semiconductor sub-regions. As a person skilled in the art would recognize, the “metal/semiconductor interface” or to any extent, the interface between any two regions or sub-regions of the nanoparticles disclosed and described herein, consists of the area on the face of the semiconductor crystal on which the metal grows during synthesis or the area on the semiconductor surface being in contact with another semiconductor material. This area of the semiconductor is, then, blocked to any other functionality and/or from the solvent molecules. From a physical point of view, the interface is the point at which the two Fermi levels (of the metal and of the semiconductor, or of the two different semiconductor materials) equalize when in equilibrium.

Once formed, as shown in Scheme 1 for one exemplary constructions of the nanoparticle, the electrons and positive holes undergo charge separation, at which stage they are capable of evoking various reactions, herein referred to as “photocatalytic reactions”, by interacting with neighboring electron acceptor and electron donor molecules. Since the holes so generated have oxidizing power, and the electrons have reducing power, the nanoparticles acting as photocatalysts can catalyze a reduction-oxidation (redox) reaction as long as electrons and holes are formed, e.g., by light-activation. As the nanoparticles are not consumed in the process and do not lose their ability to undergo the light-induced process described (thus termed “photocatalysts”), their function depends on the presence of a light source or their ability to retain charge and undergo such a process even in the absence of light.

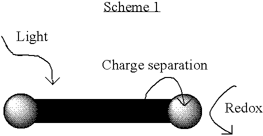

Scheme 1: A general and exemplary illustration showing the photocatalytic activity of a metal/semiconductor hybrid nanoparticle. The activity is initiated by a photon that forms an electron-hole pair, one of the charge carriers stays in the semiconductor (in this example—the central elongated portion of the nanoparticle) while the other moves to the metal (in this example—one of the regions at the ends of the elongated portion) and is available to react, in this particular example, with a redox reagent.

Generally, the nanoparticles employed as photocatalysts may be divided, for purposes herein, into two groups: nanoparticles known in the art and nanoparticles according to the invention.

In some embodiments, the nanoparticle is a nanoparticle comprising at least one metal/metal alloy region and at least one semiconductor region having an absorption onset in the visible (400-700 nm, in some embodiments above 420, or above 450 or above 500 nm) to near infrared (NIR) range (0.7-3 μm), said nanoparticle being capable of forming, upon irradiation (illumination) with a radiation in the visible and/or NIR range, an electron-hole pair at the metal/semiconductor interface and subsequently undergo charge separation. In certain embodiments, where the nanoparticles have elongated shape, they may be prepared as disclosed in [15]: International Publication No. WO 05/075339, or a US Application derived therefrom, herein incorporated by reference. However, the shape and size of the nanoparticle so defined may vary, as the photoactivity of the nanoparticles is by no way dependent solely on the elongated structure.

In some embodiments, the nanoparticle of the invention comprises at least two metal/metal alloy regions, separated by at least one semiconductor region, wherein each of said at least two metal/metal alloy regions is of a different or same metal/metal alloy material (namely having different or same Fermi potentials, respectively).

In some embodiments, each of said at least two metal/metal alloy regions is of a different metal/metal alloy material (having different Fermi potentials).

In some embodiments, the two metal/metal alloys are of the same metal/metal alloy material.

In other embodiments, the nanoparticle of the invention comprises at least two metal/metal alloy regions, separated by at least two semiconductor regions, wherein each of said at least two metal/metal alloy regions is of a different or same metal/metal alloy material (namely having different or same Fermi potentials, respectively), and each of said at least two semiconductor regions having a different energy gap and/or different energy band positions.

In some embodiments, the at least two semiconductor regions are separated by at least one metal/metal alloy region.

In other embodiments, said at least two semiconductor regions are not separated by one or more metal/metal alloy region and are therefore referred to herein as “sub-regions”. The two or more semiconductor sub-regions are each of a different semiconductor material.

Within the context of the present invention, the term “material” refers to a solid substance of which the nanoparticles or any one region thereof is made. The material may be composed of a single substance, e.g., elements, alloys, oxidized forms, etc, or a mixture of such substances, at any ratio.

The nanoparticle of the invention or the nanoparticle employed by the methods of the invention, as will be disclosed further hereinbelow, is a discrete entity wherein at least one of its dimensions (e.g., diameter, length, etc) is between 1-20 nm. It may have a rod-like structure having a length of below 400 nm, preferably below 200 nm. The nanoparticles may also be in the form of a nano-network form, as will be further detailed hereinbelow, of few microns in overall size. Where the overall shape of the nanoparticle is spherical or disk-like, the largest dimension is the diameter of the sphere or disk.

Notwithstanding the above, the nanoparticle can have any shape and symmetry, and may display branched and net structures. Without being limited thereto, the nanoparticle may be symmetrical or unsymmetrical, may be elongated having rod-like shape, round (spherical), elliptical, pyramidal, disk-like, branch, network or have any irregular shape.

The use of the term “particle” is by no way to suggest any one particular pre-defined shape. In view of the variability in structure and symmetry, shape and to some extent size, the nanoparticle of the invention may also be referred to, interchangeably, as a “nanostructure”.

In some embodiments, the nanoparticle is a nanorod having elongated rod-like shape.

In some other embodiments, the nanorods are constructed of a semiconducting material having at one or both ends a metal or metal alloy region.

As used herein, the term “region” refers to a continuous segment of the nanoparticle which is defined by its chemical composition. The regions may be confined by a region of a different material, e.g., semiconductor region confined by metal/metal alloy regions, or may be at a terminal region defining the ends of the nanoparticle. Thus, the semiconductor region is the part composed of a semiconducting material and the metal/metal alloy region is composed of a metal, a metal alloy or a combination thereof, at any ratio. Each of the regions may be further segmented into “sub-regions”, each composed of a different type of semiconducting material or metal/metal alloy material. For example, a semiconductor region may be segmented into two or more sub-regions having a common interface, each composed of a different semiconducting material. As the sub-regions are part of a single semiconductor region (or in other examples a metal/metal alloy region), the sub-regions are in contact with each other and continuous (namely having a common interface, lacking any dividing region of any thickness or composition), confined by the sub-regions or regions of the metal/metal alloy region (or semiconductor region).

In other embodiments, the nanoparticle is in the form of a continuous surface of a semiconducting material having thereon spaced apart regions of at least one metal/metal alloy material. The continuous surface of the semiconducting material may be the surface of a nanosphere, nanorod, or any other shaped-regular or irregular-nanostructure. In one example, the nanoparticle is a nanorod being composed of at least one semiconductor, the surface of which being spotted with one or more spaced apart islands or dots of at least one metal/metal alloy. Each such island may be of the same or different metal/metal alloy material. In another example, the nanorod has on one of its termini a metal/metal alloy region and on its semiconductor surface spaced apart metal/metal alloy islands or dots which may or may not be of a single material and which may or may not be of the same material as the metal/metal alloy at the terminus.

In further embodiments, the nanoparticle is in the form of a nanorod having on its surface at least one region (in the form of an island or a dot) of at least one metal/metal alloy material. In some embodiments, the nanorod has on its surface a plurality of spaced apart metal/metal alloy regions, of same or different metal/metal alloy material.

In other embodiments, said at least one nanoparticle is a plurality of such nanoparticles, herein referred to as a population of nanoparticles. This population of nanoparticles is characterized as having a narrow size distribution, shape distribution and/or a spatial arrangement, namely the arrangement of the metal/metal alloy region in relation to the semiconductor region and/or the spatial distribution of the metal/metal alloy regions on the surface of the semiconductor material.

As stated above, the nanoparticle employed by the present invention comprises at least two different regions: the one region being of a semiconducting material and the second region of a metal/metal alloy material, with the electron-hole pair being formed in an area of the semiconductor being proximal to the metal/semiconductor interface and charge separation follows. In the presence of an electron acceptor and hole acceptor, the electron and hole, independently, are transferred to their respective acceptors. The metal/metal alloy material is thus chosen so that by tuning the Fermi energy level of the metal, the tuning of the band structure of the semiconductor by size, composition and shape permits the control of which charge carrier (electron or hole) is transferred to the metal and which remains at the semiconductor. The metal/metal alloy further provides its catalytic activity for ensuing photochemical reactions.

Where the nanoparticles of the invention are constructed to have two or more distinct regions of at least one metal/metal alloy material, each region separated from the other by a region (or regions) of a semiconducting material(s), the charge separation may occur in several regions of the nanoparticles.

In such embodiments, where more than one metal/metal alloy region is present, the metal/metal alloy of a first of said more than one metal/metal alloy region may be the same as the metal/metal alloy of a second of said more than one metal/metal alloy region. In some embodiments, the metal/metal alloy material of a first of said more than one metal/metal alloy region is different from the metal/metal alloy material of a second of said more than one metal/metal alloy region.

In some other embodiments, where more than one metal/metal alloy region is present, each of said first and second metal/metal alloy materials as well as any further metal/metal alloy material of said more than one metal/metal alloy region has a different Fermi potentials, thereby facilitating charge separation.

Non-limiting examples of meta/metal alloy pairs of different Fermi potentials are gold and palladium; platinum and palladium; silver and gold; silver and platinum; and silver and palladium. Copper, iron as well as transition metals such as manganese, cobalt, ruthenium, etc, may also be employed.

In some embodiments, the metal/metal alloy materials having different Fermi potentials are gold and palladium, where gold, with the higher Fermi energy acting as an electron acceptor and palladium, with a lower Fermi energy, acting as hole acceptor on the nanoparticle.

In certain embodiments, where the nanoparticle of the invention is constructed to have two or more regions of semiconducting material, each of said two or more regions may be of the same semiconducting material (for example with several metal/metal alloy regions deposited on them), so as to enable several similar charge separation reactions to take place along the nanoparticle.

In some alternative embodiments, the region of the semiconducting material may be in the form of a single continuous region having sub-regions of different semiconducting materials, each semiconducting material differing from the other in composition and hence in band gap and electronic band alignment. In one such non-limiting example, the nanoparticle of the invention is constructed of two semiconductor sub-regions, forming a ‘type II’ (staggered) semiconductor interface in which both the valence band and conduction band alignments of one semiconductor in one sub-region is energetically higher than the alignments of the semiconductor in the other sub-region. In such a nanoparticle construction the electron and hole separate to different semiconductor regions followed by further separation into the metal/metal alloy islands.

In yet other embodiments, the nanoparticle is a nanorod with a first metal/metal alloy region of a metal/metal alloy material having high Fermi potential, at one end, and a second metal/metal alloy region of a metal/metal alloy material having a lower Fermi potential, at a second end, the elongated region between said first and second ends being segmented into two sub-regions of a semiconducting material, wherein a first sub-region of said semiconducting material, having a lower conduction band energy is in contact with said first metal/metal alloy region and a second sub-region of said semiconducting material, having a valance band energy higher than that of said semiconducting material of said first sub-region and lower than the Fermi potential of said second metal/metal alloy of said second metal/metal alloy region, is in contact with said second metal/metal alloy region. This construction, shown schematically for the sake of clarity in Scheme 2 below, ensures efficient charge separation.

Scheme 2: the cascading of a hole and/or electron in a four-region
nanostructure. As illustrated, the electrons cascade in the conduction
bands of the semiconductor materials to the metal/metal alloy of a higher
Fermi energy (which is yet within the band gap), while the hole cascades
in the valence bands to the metal/metal alloy of a lower (yet within the
band gap) Fermi energy.

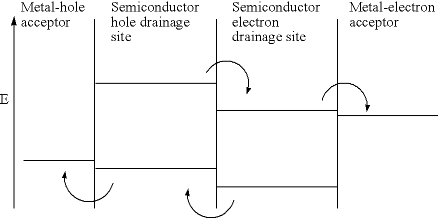

The one or more semiconductor regions are typically constructed of semiconducting materials having each an absorption onset in the visible, the visible and the near infrared range or even at deeper infrared then 3 μm. While some of the semiconducting materials may have the ability to also absorb in the UV range, the semiconducting materials employed in the nanoparticle of the invention do not solely absorb in the UV range.

Without wishing to be bound by theory, different semiconducting materials have different band gap energies and hence different optimal wavelength absorbances. Nanometric particles of such semiconductors absorb at different tunable wavelengths as a function of the particle size and generally at shorter wavelengths from the bulk material, and the semiconducting materials of the nanoparticles used should thus be chosen in accordance with the irradiation wavelength, or the combination of wavelengths intended to be employed in a specific method or a specific application. It is also possible to use several populations of nanoparticles, each with its own semiconducting material/size and absorbance range to enable efficient reaction over a broad light spectral region. Changing the semiconducting material enables the tuning of the band-gap and band-offsets to expand the range of wavelengths usable by the nanostructure and to tune the band positions for, e.g., redox processes.

The semiconducting materials are thus selected from elements of Group II-VI, such as CdSe, CdS, CdTe, ZnSe, ZnS, ZnTe, HgS, HgSe, HgTe and alloys thereof such as CdZnSe; Group III-V, such as InAs, InP, GaAs, GaP, InN, GaN, InSb, GaSb, AlP, AlAs, AlSb and alloys such as InAsP, CdSeTe, ZnCdSe, InGaAs; Group IV-VI, such as PbSe, PbTe and PbS and alloys thereof; Group III-VI, such as InSe, InTe, InS, GaSe and alloys such as InGaSe, InSeS; Group IV semiconductors, such as Si and Ge alloys thereof, and combinations thereof in composite structures and core/shell structures. In some embodiments, the nanoparticle of the invention comprises semiconducting materials selected from Group II-VI semiconductors, alloys thereof and core/shell structures made therefrom. In further embodiments, the Group II-VI semiconductors are CdSe, CdS, CdTe, ZnSe, ZnS, ZnTe, alloys thereof, combinations thereof and core/shell, core multi-shell layered-structures thereof.

In some embodiments, the semiconducting material is other than TiO₂.

The metal/metal alloy materials are typically transition metals. Non-limiting examples of such are Cu, Ag, Au, Pt, Co, Pd, Ni, Ru, Rh, Mn, Cr, Fe, Ti, Zn, Ir, W, Mo, and alloys thereof.

In some embodiments, the metal is Au, Pd, and Pt and alloys thereof.

In further embodiments, the metal is Au, Pd, and Pt and alloys thereof and said at least one semiconductor material is CdS, CdSe or CdTe.

For catalyzing photochemical reactions, a single as well as a plurality of nanoparticles may be employed. A population of nanoparticles may be characterized as a collection (blend) of nanoparticles, each characterized as disclosed herein, wherein the population is further characterized as having at least one of chemical processability and/or predefined distribution. In some embodiments, a population of nanoparticles is characterized as having both chemical processability and predefined distribution.

The chemical processability of the nanoparticle population refers to the ability to manipulate and chemically modify and treat the surface of the nanoparticles to obtain a controlled distribution of the nanoparticles in a medium in which homogenous or predetermined distribution is sought Such a medium may be a liquid medium, including aqueous and non-aqueous solutions, a gel, or a solid medium such as a polymer, a film, an electrode and various other surfaces, or mixtures thereof.

In some embodiments, the distribution is in the form of an aggregate. In other embodiments, the distribution is in the form of a non-aggregated net-like distribution.

As stated above, the nanoparticles of the present invention have a relatively narrow size distribution, namely they are manufactured in a relatively narrow range of sizes. In fact, the standard deviation (sigma) of the particles' size in a single population is typically less than 25%. In some embodiments, the deviation in the particles size is less than 15%. Where the nanoparticles are elongated (nanorods) the sigma of the length of a single population is less than 35% and the sigma of the width is less than 15%.

The narrow size distribution allows the designing of homogenous populations of nanoparticles having one or more of the following advantages:

a) reproducibility of the photocatalytic reactions employing such populations,

b) simplified arrangements and assemblies in arrays, and/or

c) ability of tuning the electronic properties including the absorption to optimise harnessing solar energy and band alignment to optimise the photocatalytic activity.

In some embodiments, the population of nanoparticles is homogenous in that said population comprises nanoparticles of relatively the same size and/or shape.

In other embodiments, the population of the nanoparticles is a blend of two or more different populations, each of which having nanoparticles of different sizes (or size distributions) and/or shapes.

For certain applications it may be desirable to vary not only the size and shape of the nanoparticles, making up the population, but also the chemical composition of the nanoparticles and/or the arrangement of the semiconductor and metal/metal alloy regions along the nanoparticles. Thus, in some embodiments, the population of nanoparticles is a blend of one or more of the following types/groups of nanoparticles:

1) nanoparticles of a certain pre-determined size distribution;

2) nanoparticles of a certain pre-determined shape;

3) nanoparticles having one metal/metal alloy region and one semiconductor region (optionally having one or more sub-region of different semiconducting materials);

4) nanoparticles having at least two metal/metal alloy regions and a single semiconductor region (optionally having one or more sub-region of different semiconducting materials);

5) nanoparticles having one metal/metal alloy region and at least two semiconductor region (optionally having each one or more sub-region of different semiconducting materials);

6) nanoparticles having at least two metal/metal alloy regions and at least two semiconductor regions (optionally having one or more sub-region of different semiconducting materials),

7) nanoparticles having at least two metal/metal alloy regions and at least two semiconductor regions (optionally having one or more sub-region of different semiconducting materials), wherein the arrangement (sequence) of regions or sub-regions along the nanostructure differs from one population to another;

8) nanoparticles which may be photoactivated at only a particular wavelength or at a only predetermined wavelength or range of wavelengths;

9) nanoparticles which do not undergo photoactivation as described herein.

The population of nanoparticles may be attained by mixing together one or more of the above types of nanoparticles. Alternatively, heterogeneous populations may be prepared by employing, e.g., non-stoichiometric amounts of starting materials. Each group of nanoparticles may be manufactured separately and stored for future use. As a person skilled in the art would realize, each of the above groups of nanoparticles may be prepared in a substantially uniform or homogenous fashion. However, due to random defects having to do with e.g., the manufacture process, purity of starting materials and other factors, a certain degree of nanoparticles having defects in size, shape, chemical composition, and other parameters, may be found in each of these types of nanoparticles. It should be noted that the presence of such defects does not necessarily reflect on any one of the herein disclosed characteristics and in particular on their photocatalytic activity.

A population of nanoparticles may comprise a blend of nanoparticles of one or more of the above types, in a known pre-determined ratio of nanoparticles or comprise a random mixture of such nanoparticles. In a certain non-limiting example, a population of nanoparticles comprises nanoparticles having a large variety of sizes and shapes, constructed of a single metal/metal alloy region and two semiconductor regions (optionally having one or more sub-region of different semiconducting materials). In another example, a population of nanoparticles may comprise nanoparticles of different shapes and different chemical compositions. In yet another example, the population comprises a blend of nanorods having at least one metal/metal alloy region at one or both ends of the elongated structure and/or at least one metal/metal alloy region in a central, non-terminal part of the elongated nanostructure.

In addition, nanoparticle populations comprising any one nanoparticle according to the invention or employed in any one method of the invention, and at least one type of particle outside of the scope of the present application are also provided herein. Such mixed populations of nanoparticles herein described and nanoparticles known in the art may have advantageous effects suitable for any one application disclosed herein.

As will be discussed further below, by having the ability to provide blends of different nanoparticle populations it is possible to tune the optical properties of the material, thus utilizing the whole range of wavelengths efficiently. Alternations in the metal composition and size allow the fine-tuning of the Fermi level energy and the redox potential of the nanostructure. The different shapes enable better control and the design of a great variety of devices.

As will be further shown below, the nanoparticle populations of the invention may form a net-like arrangement, herein referred to as “nanonets”, with the individual nanoparticles strongly interacting with each other to create a single net-like structure as shown, for example, in FIGS. 11b, 11c and 11d. In the nanonet structure, the semiconductor segments are fused with covalent binding, resulting in strong coupling between the segments and the surface is decorated with metal islands.

It is emphasized that the nanonet structure results in a structure that is by no means a mere random aggregation or collection of nanoparticles. Such a random aggregation or collection is typically characterized as having an overall low surface area resulting from the blocking (partially or wholly) of the surface area of the individual nanoparticles due to the three-dimensional structure of the random aggregate. Such aggregates are less stable and decompose under less stringent conditions to smaller aggregates or to the individual nanoparticles.

Unlike a random aggregation or collection of nanoparticles, the nanonet structures of the invention are more porous, having a more exposed high surface area structure composed of interconnecting (fused) nanostructures. In fact, when nanonets of the invention are inspected it is nearly impossible to distinguish the contact points between the original nanoparticles, e.g., nanorods or spherical-like particles that were used to prepare this structure.

As experiments have shown, in typical aggregates, the photocatalytic activity may be reduced or quenched. The nanonets of the invention exhibit photocatalysis activity and are in a form that is desirable for a photocatalyst since they can easily become stationary on a substrate or membrane structure and could easily be separated from a photocatalysis reaction solution.

Thus, the invention also provides nanonets originating from nanoparticles. The diameter of the net ‘arms’ is typically 1-50 nm. The extent of the bundled nanonet can vary from the tens of a nanometer scale to few micrometers.

As with heterogeneous populations of nanoparticles, the nanonets too may be heterogeneous, namely constructed of nanoparticles of various sizes, shapes, chemical compositions, etc.

In other embodiments, the nanonets are originally prepared from nanorods.

In further embodiments, the nanorods are homogenous or heterogeneous in terms of chemical composition and/or size.

As stated hereinabove, the nanoparticles, populations containing them, or nanostructures thereof, in accordance with the invention may be used as photocatalysts in a variety of photo-induced reactions. Such photo-induced reactions may be one or more of water splitting; purifications of water and air from contaminates through e.g., decomposition of such contaminants; deodorization; treatment of industrial effluent and exhaust; chemical transformation of organic contaminants, such as residues from the dye industry, into less toxic and more environmentally safe agents; antibacterial applications; anti-clouding applications, and generally any chemical reaction involving reduction-oxidation reactions for the production of a desired intermediate(s) or end product(s) or for the elimination of a harmful contaminate.

In one embodiment, the photo-induced reaction is water splitting.

In other embodiments, the water splitting reaction is induced by sunlight.

In order to achieve photocatalysis, the nanoparticles are contacted with at least one charge carrier acceptor (such as a redox couple, electrode, electrode/redox couple), under appropriate conditions, where the redox couple usually accepts charges via collision in solution (e.g., liquid, gel, polymer, etc), whereas the contact to an electrode will be in film form or other self-assembled manner ensuring a good contact. When in contact with the charge carrier acceptor, the medium containing the nanoparticles and the at least one charge carrier acceptor are irradiated with light in the ultraviolet/visible/near infrared range. As the nanoparticles are constructed of semiconducting material(s) having an absorption onset in the visible to near IR range, and optionally also in the UV range, so as charge separation at the metal-semiconductor interface upon irradiating may ensue, the irradiation is preferably with a visible or near infrared light. Such light is abundant in solar illumination, so the most energy-saving and green illumination can be provided directly with solar light with its typical broad spectrum.

The nanoparticles of the invention are in some embodiments capable of retention of charge and can then transfer their electron to an electron acceptor, e.g., in a redox reaction, in the absence of continuous irradiation. In other words, the nanoparticles may be pre-irradiated, namely irradiated in the presence of only one type of charge acceptor and prior to coming into contact with the acceptor of the opposite charge carrier type, and thus be excited creating an electron-hole pair. One of the carriers can then be transferred for an acceptor, for example a hole acceptor, leaving the opposite charge, for example the electron, on a specific segment of the photocatalyst. This excess charge can be retained for a significant period of time. When the charged nanoparticles are brought into contact with the charge carrier acceptor of the second type, a reduction of the acceptor molecule may occur in the absence of visible or NIR light and even in the dark.

In one exemplary case of a blend of CdSe nanorods and gold nanoparticles, the charge is retained on the gold nanoparticles in the solution and is transferred through a productive collision from an excited CdSe nanorod. Using the Stokes-Einstein relations the average collision time between the gold nanoparticles and the CdSe nanorods was estimated at approximately 1 nsec which is significantly longer than the lifetime of the exciton in the CdSe nanorod (10 nsec). However, in the presence of ethanol as hole scavenger at a significant volume fraction in the irradiated solution, or other hole acceptors, hole transfer from the excited CdSe nanorod is allowed, leaving a negatively charged rod that transfers its excess electron to a gold nanoparticle during a collision. In the case of elongated structures having the general construction of NDBs the much more effective retention of charge on the gold at both ends of the elongated structure is assigned to the rapid charge separation between the central CdSe and gold regions, accompanied by hole scavenging by the hole acceptor, such as ethanol in this particular example, which prevents recombination of charge carriers. The careful design of the photocatalyst therefore enables significantly more effective activity.

Without wishing to be bound by theory and for the sake of further understanding, it is demonstrated that the number of retained electrons per NDB was roughly estimated from the amount of reduced acceptor molecules and estimation of the NDB amount using the absorbance spectra. This yielded an average retention of about 50 electrons per NDB at the longest pre-irradiation times studied. This large number can be rationalized by estimating the change in charging energy of the gold tips with addition of an electron. Accumulation of the charge on the gold tips leads eventually to Fermi level equilibration of the metal with the semiconductor part suppressing further charge separation.

It is therefore possible to use the nanoparticles of the invention, such as the NDBs, in one or a combination of the following methods of photocatalysis

1) direct photocatalysis, namely the simultaneous irradiation of a medium containing nanoparticle(s) and the charge carrier acceptor and donor, as detailed herein, to perform redox reactions directly, and/or

2) employing pre-irradiated nanoparticles (irradiated by intentional exposure to light in the presence of one type of charge carrier acceptor and absence of the opposite charge carrier acceptor and thus exhibiting retention of charge) in contact with the charge carrier acceptors in the absence of light (or at least not necessitating further light irradiation).

These methods may be utilized in the constructions of devices such as photoelectrochemical cells and photovoltaic cells, employing the general methods of the invention.

Thus, the present invention also provides in another of its aspects a method of photo-inducing charge separation and transfer of charge carriers to charge acceptors, said method comprising:

1) providing at least one nanoparticle, as disclosed herein;

2) contacting said at least one nanoparticle with at least one electron acceptor and at least one electron donor (e.g., hole acceptor) in a medium; and

3) optionally, irradiating the medium containing said at least one nanoparticle, at least one electron acceptor and at least one electron donor with a radiation in the visible and/or near IR range and optionally UV range;

thereby allowing formation of an electron-hole pair in the metal/semiconductor interface of said at least one nanoparticle and subsequent charge separation and transfer of the electron and hole to said at least one electron acceptor and said at least one electron donor, respectively.

This method allows the creation of an electron-hole pair, in the presence of light (visible and/or near infrared and optionally also, but not only, ultraviolet), and the separation of the electron-hole pair (also termed herein “charge carrier”) in the nanoparticle(s) into charges, which transfer to the respective acceptor moieties: the electron to an electron acceptor (herein referred to as an “electron acceptor”) and the hole to hole acceptor (herein referred to as an “electron donor” or “hole acceptor”). The electron acceptor molecule is selected in a non-limiting manner amongst acceptor dyes, such as methylene blue, azure B and thionine; oxygen; nitrates; iron (III) compounds; manganese (IV) compounds; sulfates; carbon dioxide; chlorinated compounds such as tetrachloroethylene (PCE), trichloroethylene (TCE), dichloroethene (DCE), and vinyl chloride (VC); water; alcohols such as methanol and ethanol and any other oxidizing molecule, where the LUMO (lowest unoccupied molecular orbital) of the molecule is lower than the Fermi level of the hybrid nanostructure.

The electron donor molecule is selected in a non-limiting fashion amongst alcohols such as methanol and ethanol, water, S²⁻ as provided from for example, Na₂S, Se²⁻ ions as provided from for example Na₂Se, SO₃²⁻ ions as provided from for example Na₂SO₃, SeO₃²⁻ ions as provided from for example Na₂SeO₃, or any other reducing molecules where the HOMO (highest occupied molecular orbital) of the molecule is higher than the Fermi level of the hybrid nanostructure.

The transfer of the electron and hole to their respective acceptors results in the reduction of the electron acceptor molecule and the oxidation of the electron donor molecule, allowing chemical transformations to take place at either the acceptor or donor molecules, and other applicable advantages. The reduction and oxidation reactions may be employed for the simultaneous reduction and oxidation of at least two organic or inorganic compounds which reduction-oxidation is sought or of the reduction or oxidation of at least one such compound in the presence of a sacrificial additive that undergoes the other of reduction and oxidation.

The present invention thus provides in another of its aspects a method for reducing at least one first organic or inorganic compound and/or oxidation of at least one second organic or inorganic compound, said method comprising:
1) providing at least one nanoparticle, as disclosed herein;
2) contacting said at least one nanoparticle with said at least one first organic or inorganic compound (being the electron acceptor) and at least one second organic or inorganic compound (being the electron donor) in a medium; and
3) optionally, irradiating the medium (containing said at least one nanoparticle, and at least one first and second organic or inorganic compounds) with a radiation in the visible and/or near IR range and optionally UV range;

thereby allowing reduction of said at least one first organic or inorganic compound and/or oxidation of said at least one second organic or inorganic compound.

In yet another aspect of the invention there is provided a method for photocatalytic production of hydrogen, said method comprising irradiating an aqueous medium containing at least one nanoparticle, as disclosed herein, and optionally at least one other charge carrier acceptor, with light in the visible and/or near IR range and optionally UV range; said light being optionally solar light to obtain hydrogen following water splitting.

Additionally, there is provided a method of degrading at least one contaminant in water or air, said method comprising:

1) introducing into a medium containing at least one contaminant at least one nanoparticle as defined;

2) irradiating said medium with light in the visible and/or near IR range and optionally UV range, thereby causing reduction or oxidation of said at least one contaminant.

Unlike the photocatalytic method reported by Bao et al [6] which employs semiconductor CdS particles, only 10% of which statistically deposited with metal (Pt), the methods of the invention make use of hybrid nanoparticles having at least a binary construction of at least one metal/metal alloy region and at least one semiconductor region composed of a semiconducting material having an absorption onset in the visible (400-700 nm, in some embodiments above 420, 450, 500 nm) to near infrared (NIR) range (0.7-3 μm).

Additionally, in contrast to the Bao particles [6], the nanoparticles employed by the methods of the invention exhibit high chemical processability and are manufactured in predefined distributions, as disclosed hereinabove, and are photoactive even in non-nanowire arrangements. Moreover, Bao is limited to the CdS confined band gap, i.e. for light with wavelength below 500, and preferably 450 nm (blue light), while the present application allows irradiation into the visible range and beyond.

The nanoparticles employed by methods of the invention are capable of forming, upon irradiation with a radiation in the visible and/or NIR range, an electron-hole pair at the metal/semiconductor interface and subsequently charge separation. An example of such a nanoparticle having elongated rod-like shape is disclosed in [1,5] International Publication No. WO 05/075339, herein incorporated by reference.

In some embodiments, the at least one nanoparticle is of an elongated shape. In other embodiments, the at least one nanoparticle is not elongated.

In some embodiments, the at least one nanoparticle employed comprises at least two metal/metal alloy regions, separated by at least one semiconductor region, wherein each of said at least two metal/metal alloy regions is of a different or same metal/metal alloy material (namely having different or same Fermi potentials, respectively).

In some embodiments, each of said at least two metal/metal alloy regions is of a different metal/metal alloy material (having different Fermi potentials).

In some embodiments, the two metal/metal alloys are of the same metal/metal alloy material.

In other embodiments, the nanoparticle employed by any one method of the invention comprises at least two metal/metal alloy regions, separated by at least two semiconductor regions, wherein each of said at least two metal/metal alloy regions is of a different or same metal/metal alloy material (namely having different or same Fermi potentials, respectively), and each of said at least two semiconductor regions having a different energy gap and different energy band positions.

In some embodiments, the at least two semiconductor regions are separated by at least one metal/metal alloy region.

In other embodiments, each of said at least two semiconductor regions is of a different semiconducting material, said regions not separated by a metal/metal alloy region.

In some embodiments of the methods of the invention, the at least one nanoparticle is a nanorod.

In further embodiments, the nanorod is in the shape of a NDB, having at one of its ends a first metal/metal alloy region and on the other of its ends a second metal/metal alloy region, the first and second metal/metal alloy regions differing from each other in their chemical composition, i.e., Fermi potential.

In additional embodiments, the NDB has at least one additional metal/metal alloy region in the elongated segment of the nanostructure.

In some embodiments, the at least one nanoparticle is a population of particles.

In some other embodiments, the population of nanoparticles is homogenous, namely containing a single type of nanoparticles or heterogeneous, namely containing a blend of nanoparticles.

In further embodiments, the population of nanoparticles, as defined, is brought into contact with said at least one charge carrier acceptor or at least one charge carrier donor in a medium which may be aqueous, organic or mixtures thereof. In some embodiments, the methods of the invention are carried out in aqueous solutions comprising at least one electron donor molecule.

For the transfer of each of electron and hole to their respective acceptors, the nanoparticles, aggregate, nanonet or any other population thereof must be in contact with the electron and hole acceptor molecules in the medium. Within the context of the present invention, the term “contacting” or any lingual variation thereof refers to the bringing together of said at least one acceptor molecule and said at least one nanoparticle to allow charge transfer between said at least one nanoparticle and said at least one acceptor molecule, thereby ensuing reduction or oxidation of the acceptor molecule (whether electron acceptor or hole acceptor). The contact between the one or more nanoparticles and one or more of the acceptor molecules may with the acceptor molecules being dissolved in a solution and the nanoparticles constructed as part of an electrode (with or without bias), embedded in a matrix, deposited as mono- or multi-layered films and/or freely distributed in a medium. For some applications, the acceptor molecules and the nanoparticles are in the same physical or chemical environment, namely embedded in a matrix, deposited as layers, etc.

In other embodiments, the method is carried out under sunlight regardless of the nanoparticles population employed and the chemical transformation to be achieved.

As may be understood to one versed in the art from the disclosure provided herein, the hybrid nanoparticles may be used as photocatalysts in a variety of photo-induced chemical transformations. There are several advantages for using the hybrid nanoparticles of the invention as photocatalysts over previous technologies.

First, the population of nanoparticles may be tailored by choosing the semiconductor to tune its band gap and band-offsets as required for the particular photo-induced process [13]. Quantum confinement effects can be used by tuning the size of the semiconductor region so as to shift the gap and the band positions to match specific photocatalytic processes. This allows wide spectral coverage to efficiently harness solar energy, and allows for tuning the band offsets between the particle, the metal (or metal alloy), and the redox couple. Moreover, heterostructured nanoparticles and rods can be prepared, which already provide a useful energy landscape for charge separation and limit competing recombination processes.

Second, the metal/metal alloy may be chosen and used to enhance catalytic activity, tune the energy level positions and enable photo-induced processes.

Third, the nanometric particles have a high surface area presenting many reaction centers, thus potentially increasing their efficiency.

Fourth, the nanoparticles are chemically accessible and through surface manipulations and ligand exchange [14], can be solubilized in organic or polar solutions including water, deposited as mono- or multi-layered films or bound to surfaces on, e.g., electrodes, providing wide flexibility in their applications in photocatalysis and the other applications discussed above.

Non-limiting examples of photocatalytic reactions which may be catalyzed by the nanoparticles of the invention are water splitting, purifications of water and air from contaminates, chemitransformation of organic contaminants, such as residues from the dye industry, into less toxic and more environmentally safe agents, and generally any chemical reaction involving reduction-oxidation reactions for the production of a desired intermediate(s) or end product(s) or for the elimination of a harmful contaminate. The type of the photocatalysis reaction employing the nanoparticles of the invention depends on the nanoparticle or nanoparticle population (homogenous/heterogeneous) and the redox couple used. The energy band alignment of the semiconductor's conduction and valence bands and the metal's Fermi energy will determine a specific window of redox couples that may be used.

In some embodiments, the methods of the invention are used as a method of photocatalysis for the generation of hydrogen gas in a water splitting process. In such embodiments, the method of the invention may be carried out in a photoelectrochemical cell and the charge carrier acceptors are in the form of an electrode and a redox couple.

In further embodiments, the method of the invention is used for photo-voltage production; employing, in certain embodiments, a charge carrier in the form of an electrode. In such embodiments, the method may be carried out in a solar cell device.

In further embodiments, the method of the invention is used for the production of electric currents in a circuit or for producing electric energy that may be, e.g., stored in a battery. In such embodiments, the method of the invention may be carried out in a photoelectrochemical cell and the charge carrier acceptors are in the form of an electrode and a redox couple.

The present invention, thus, further provides, in another of its aspects, a device comprising at least one nanoparticle according to the present invention. Non-limiting examples of such a device are a solar cell, a photoelectrochemical solar cell, a device for photochemical treatment of contaminants and a device for photocatalysis of chemical reactions. The devices may be used as single cells or as arrays thereof.

The device of the invention may comprise a population of nanoparticles as defined herein.

In one embodiment, the device of the invention is a photoelectrochemical cell including in one particular construction an electrode arrangement, e.g., comprising a negative and a positive and optionally a gate electrode, provided as constituents with an electrolyte solution, e.g., I⁻/I₃⁻, interposed between them. In the construction, a plurality of nanoparticles, as disclosed herein, is deposited on one of said two electrodes, e.g., the negative electrode, with at least one of the metal/metal alloy regions of each of said nanoparticles being in contact with said electrode and the semiconductor region being exposed to the electrolyte. Upon irradiation of the cell, or the electrode component being deposited with the nanoparticles, the nanoparticles undergo the sequence of events disclosed herein, generating electromotive force across the positive and negative electrodes.

In some embodiments, one or both of said electrodes is ITO. In other embodiments, one or both of said electrodes is a transparent electrode.

The photoelectrochemical cells may be used for the photoelectrical-induction of chemical reactions. Such a cell may be utilized for the photoelectrical-induction of contaminant degradation, reduction and/or oxidation of one or more organic and/or inorganic compounds, water-splitting in the presence or absence of at least one sacrificial compound and other chemical transformations.

In another embodiment, the device of the invention is a photovoltaic cell including in one particular construction two electrodes with a self-assembled layer of hybrid nanoparticles placed between the two electrodes so that the different regions of each of the nanoparticles of the layer are in contact with the different electrodes, i.e., metal/metal alloy region to one electrode and semiconductor region to the other electrode. Following light absorption, charge separation ensues following the sequence of events disclosed herein, creating a current between the two electrodes.

In some embodiments one or both of said electrodes is ITO. In other embodiments, one or both of said electrodes is a transparent electrode.

### BRIEF DESCRIPTION OF THE DRAWINGS

In order to understand the invention and to see how it may be carried out in practice, specific embodiments will now be described, by way of non-limiting example only, with reference to the accompanying drawings, in which:

FIG. 1 generally illustrates the absorption of light by a nanoparticle of the invention constructed as a nanodumbbell. As shown, the electron and hole pair separates to different regions of the nanoparticle, e.g., electron to the metal region and hole to the semiconductor region or vice versa, allowing the redox of an organic or inorganic compound. In this embodiment, the nanoparticle is employed for the generation of hydrogen from water via the so-called water-splitting process.

FIG. 2A is an embodiment of the invention, generally illustrating a light induced charge separation mechanism in a nanodumbbell in which the photogenerated electron-hole pair separates so that the electron resides at the gold tip and the hole at the CdSe nanorod. The scheme also depicts the transfer of the hole to the scavenger and the reduction of an exemplary molecule, methylene blue, MB, upon electron transfer from the gold tip. The inset shows the energy band alignment between the CdSe and Au. FIG. 2B presents TEM image of the CdSe—Au hybrid nanodumbbells synthesized in an aqueous solution.

FIG. 3 depicts the size distribution of gold tips on ˜22×4 nm nanodumbbells for gold tips grown in a water solution.

FIG. 4 shows the absorbance spectra of cdSe rods (˜38×4 nm) in chloroform solution (bottom line) and the same nanorods in aqueous solution (middle line) demonstrating that the excitonic peak is maintained, and after growing gold tips on them in aqueous solution (top line) where the exciton feature is washed out (spectra are shifted vertically for clarity).

FIG. 5 shows a TEM image of nanodumbbeus grown in total darkness conditions. Gold growth is seen even without light. The TEM grids used for this analysis were hydrophobic carbon coated grids, and as a result, nanodumbbells aggregated upon deposition and solvent evaporation.

FIG. 6 shows the length distribution of CdSe nanorods templates in aqueous solution and of CdSe—Au nanodumbbells from the same nanorods showing a distinct shortening of the rods' length due to sacrificial etching of the CdSe upon the reduction of gold.

FIG. 7 shows TEM images of CdSe—Au nanodumbbells (˜40×4 nm): FIG. 7A before and FIG. 7B after 30 minutes of irradiation using 532 nm laser, demonstrating a similar morphology of the particles after irradiation. The presence of a buffer solution causes aggregation on the TEM grid and a reduced contrast.

FIG. 8A shows a set of absorbance spectra of MB-nanodumbbells solution in which the double peak absorbance feature of the MB is noticeable, each spectrum relates to a different pre-irradiation time at 532 nm of the particle solution before addition of the MB. FIG. 8B shows the normalized concentration of MB dye reduced by CdSe nanorods-gold nanoparticles mixture (open blue triangles) and by hybrid CdSe—Au nanodumbbells solution (open black squares) versus pre-irradiation time. High efficiency of the charge retention in the nanoparticles is demonstrated, leading to activity towards MB reduction.

FIG. 9 summarizes the simultaneous irradiation experiments for photocatalysis of nanoparticles irradiated at 473 nm. Time trace of normalized concentration of MB dye in MB mixtures with gold nanoparticles of 4 nm (red line), gold nanoparticles of 6 nm (green line), CdSe nanorods (blue line) and CdSe—Au nanoparticles (dots and black guideline). In the same time span, nanoparticles exhibit significant photoreduction activity (61% of the dye reduced).

FIGS. 10A and 10B show TEM images of gold nanoparticles used for control, experiments of simultaneous irradiation with MB. FIG. 9A is of 4 nm particles and FIG. 9B of 6 nm particles.

FIGS. 11A to 11F show TEM images of Pt growth onto CdSe nanorods in aqueous solutions at different pH conditions (scale bars 50 nm). FIG. 11A—Isolated nanorods after Pt growth at pH 10. Inset shows the original rod sample with dimensions of 70×8 nm. FIG. 11B—Intermediate state is obtained at pH 7. FIGS. 11C and 11D—pH 4 produces a nanonet structure in which Pt grows along the nanonet surface. FIG. 11E—At a very highly acidic conditions, e.g., pH 1, only the net is formed, without apparent Pt growth. FIG. 11F—Absorption spectra of the CdSe—Pt hybrids grown at different pH conditions. From bottom to top: the nanorods in water and the nanorods after growth of platinum at pH 10, pH 7, pH 4 and pH 1. Spectra are offset vertically for clarity. At pH 10 the absorbance of the hybrid still shows some of the excitonic structure.

FIGS. 12A and 12B depict the size distribution of platinum dots on 70×8 nm CdSe nanorods. The mean sizes of Pt dot are 3.3±1.1 nm and 1.9±0.5 nm at pH 10 and 4 respectively. FIGS. 12C-12D show the histograms of the nearest neighbors distance between Pt dots. The mean nearest neighbor distances are 5.3±2.0 nm and 3.3±0.7 nm at pH 10 and 4 respectively. More then 200 nanorods were examined for each histogram.

FIG. 13 shows the powder X-ray diffraction spectra of CdSe rods before (1) and after (2) Pt growth. Bulk CdSe and Pt peaks are marked. The (111) plane of the Pt can be resolved.

FIG. 14A depicts the HRTEM image of a single CdSe—Pt hybrid grown at pH 10. The CdSe lattice for the rod is seen. Inset—FFT algorithm was used and (111) plane of Pt nanocrystals was determined. FIG. 14B shows the HRTEM and FIG. 14C shows the HAADF-STEM images of CdSe—Pt hybrid at pH 4 forming nanonets.

FIGS. 15A to 15D demonstrate the photocatalysis of CdSe—Pt hybrid. FIG. 15A is a schematic demonstration of a light induced charge separation process in a CdSe—Pt nanorod, followed by photocatalytic activity on a nanorods-shaped nanoparticle having metal islands on its surface. FIG. 15B shows the absorbance spectra of MB and CdSe—Pt nanonets mixture before and after 60 min of irradiation. The peak diminishes after irradiation. FIG. 15C shows the time trace of normalized concentration of MB dye in a sol of CdSe—Pt nanonets and in isolated CdSe—Pt, both measured at pH 7. These plots display the average results of several different experiments with similar properties. The nanonets are more reactive (46% of the dye reduced) than the isolated CdSe—Pt (25% of the dye reduced). The black line is the result of a mixture of MB dye, CdSe nanorods and Pt dots (2 nm diameter) which shows only 5% of the dye reduced. FIG. 15D shows the sequential photocatalysis experiment of the CdSe—Pt nanonet showing three injections of MB at various times (the second and third are half bathes) during irradiation of the nanonets sample.

FIG. 16 is an illustration of an exemplary photovoltaic cell according to the present invention.

FIG. 17 is an illustration of an exemplary photoelectrochemical cell according to the present invention.

### DETAILED DESCRIPTION OF EMBODIMENTS

Visible light photocatalysis is a promising route for converting solar energy to chemical energy. Semiconductors and metal-semiconductor hybrid materials have been studied as photocatalysts in photochemical water-splitting to produce hydrogen, in photoelectrochemical cells and in photochemical purification of organic contaminants and bacterial detoxification. So far, semiconductor/metal hybrid photocatalysts were based mostly on wide-gap semiconductors limiting their applicability to the UV range, which consists of less than 5% of the solar spectrum. Additionally, they were poorly controlled in terms of the semiconductor particle and metal island size, shape and location thus limiting their understanding and controlled improvement.

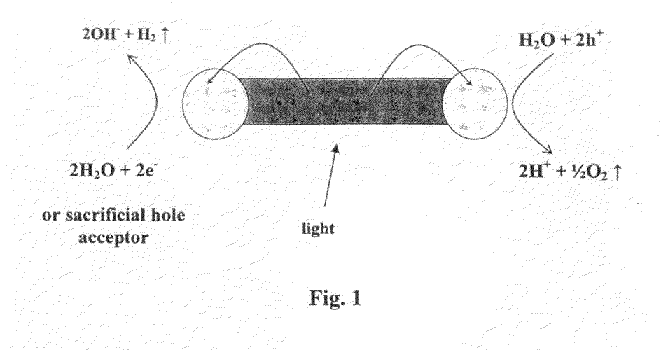

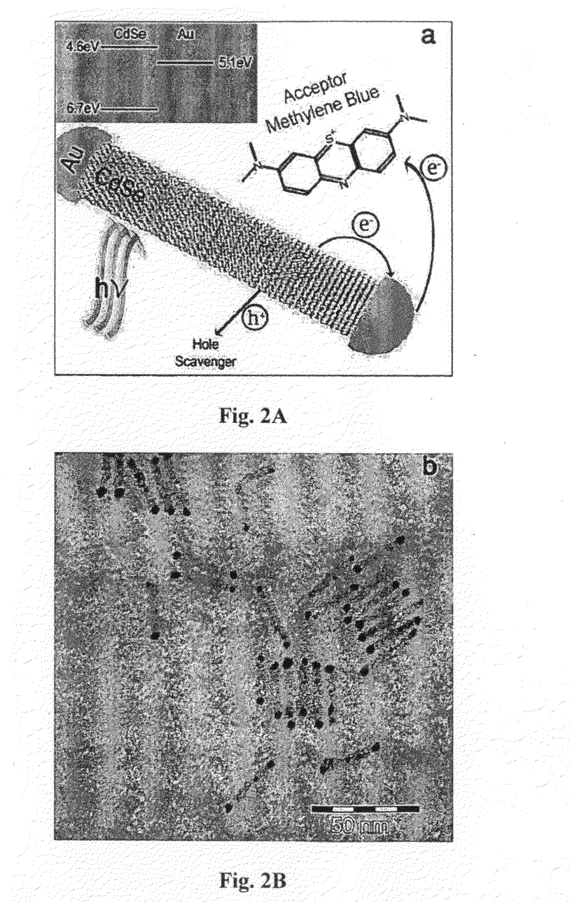

The inventors of the present invention demonstrate the visible range photocatalytic activity of highly controllable hybrid gold tipped CdSe nanorods, herein termed nanodumbbells (NDBs). As stated above, following light absorption, rapid charge separation takes place at the metal/semiconductor interface and the separated charges can perform redox chemistry of diverse forms, as schematically shown in FIG. 1 for the case of water splitting, and in FIG. 2A for another specific example using model acceptor compound. Additionally, nanodumbbells may retain charges during irradiation for later use in redox reactions.

For photocatalysis with semiconductors, it is necessary to suppress the recombination of the electron-hole pair formed following light absorption. In large gap oxide semiconductors such as TiO₂ and ZnO, metal islands deposited on the structures served to promote charge separation and also exhibited charge retention. Recently, a three component CdS—Au—TiO₂ nanojunction system was developed to achieve vectorial electron transfer and suppress charge recombination, but again the spectral coverage was limited. Also, CdS—Pt hybrid materials have shown visible light photocatalysis for water splitting. In the studies leading to the present invention a CdSe system with size-tunable visible absorption was used as a basis for the photocatalyst, taking advantage of its highly developed synthesis allowing production of spherical, rod- and tetrapod-shaped particles. Charge separation in CdSe nanoparticles was previously demonstrated using molecular complexes or semiconducting polymers. Here, well controlled growth of Au tips onto the CdSe rods was employed to separate the charges. Analysis of the band offsets between Au and CdSe shows that rapid electron transfer from the conduction band of CdSe to the Au tips is possible, leading to charge separation (inset of FIG. 2A).

The synthesis of hybrid CdSe—Au nanodumbbells was achieved in several ways. First, semiconductor nanorods (for example, 40 nm in length, 4 nm in diameter) capped with organic ligands (combination of tri-octylphosphone oxide TOPO, and phosphonic acids such as tetra-decyl phosphonic acids TDPA) were synthesized in organic medium based on published procedures [16]). The metal growth onto the tips of the nanorods was achieved either in an organic solution [19] or in an aqueous solution.

Photocatalysis is most relevant in aqueous solutions. While there is a possibility to transform the solubility of the NDBs, as achieved, from organic to aqueous phase via appropriate ligand exchange, this method may be time consuming and difficult to realize for large amounts. Instead, a new method to synthesize NDBs directly in aqueous solution is herein introduced. This method is readily expanded to growth of additional metals aside from Au onto the semiconductor nanoparticles, using the wide selection of available water soluble metal ion precursors. The control of the metal tip material is deemed as an essential and powerful knob to tune the photocatalytic activity of this system.

In this new approach, CdSe nanorods (˜38×4 nm) were grown by high-temperature pyrolysis of suitable precursors in a coordinating solvent containing a mixture of trioctylphosphineoxide and phosphonic acids, as reported previously [1,6]. CdSe nanorods were transferred to an aqueous solution by ligand exchange [17,18]. [20]. The nanorods as prepared (approximately 20 mg) were dissolved in approximately 4 ml of chloroform in the presence of a large excess of mercaptoundecanoic acid (MUA, about 4 mg). 3 ml of a KOH solution in triple distilled water (TDW) at a pH of 13 was added to the vial with the chloroform solution and shaken to obtain a milky brown solution. Next, the solution was centrifuged for 30 sec at 6000 RPM, affording two phases, a bottom organic phase and a top colored non-scattering aqueous phase indicating good nanorod transfer to the water phase. The aqueous phase was separated and the nanorods were precipitated and washed by adding methanol in a ratio of 1:3 TDW to methanol. Centrifuging at 6000 RPM for one minute allowed the separation of the nanorods from the solvent. The cleaned rods were then re-dispersed in 4 ml TDW and their concentration was determined by absorbance measurement to be around 3×10⁻⁷M.

In the next stage, AuCl₃, was weighed to a concentration of about 8000 gold atoms per CdSe nanorod, and dissolved in 2 ml TDW. The gold solution was added at once to a vigorously stirred aqueous nanorod solution and an instant color change was observed from a clear-brown solution to a murky black solution. This suspension was centrifuged at 6000 RPM for 1 minute and the precipitate was dried. The precipitate was re-dispersed in TDW to any chosen concentration. This constituted the product hybrid Au—CdSe photocatalytic nanoparticles used for further examination and a multitude of applications.

Gold (III) chloride was weighed, at a ratio of ˜1:8000 nanorod to gold atoms, and dissolved in 4 ml of TDW (triple distilled water). The gold solution was added at once to the nanorods solution under vigorous stirring and ambient light A black precipitate appeared within 30 seconds and was left to stir for two hours after which the black precipitate (nanodumbbells) was collected using centrifuge and dried. This also serves as a cleaning procedure for excess ions. The precipitate was fully re-dispersed in a TDW buffer solution of pH 7 after 20 minutes of sonication. At the neutral pH, a clear and stable solution was obtained, while at more acidic conditions the precipitate did not dissolve well likely due to the abstraction of the MUA groups from the surface.

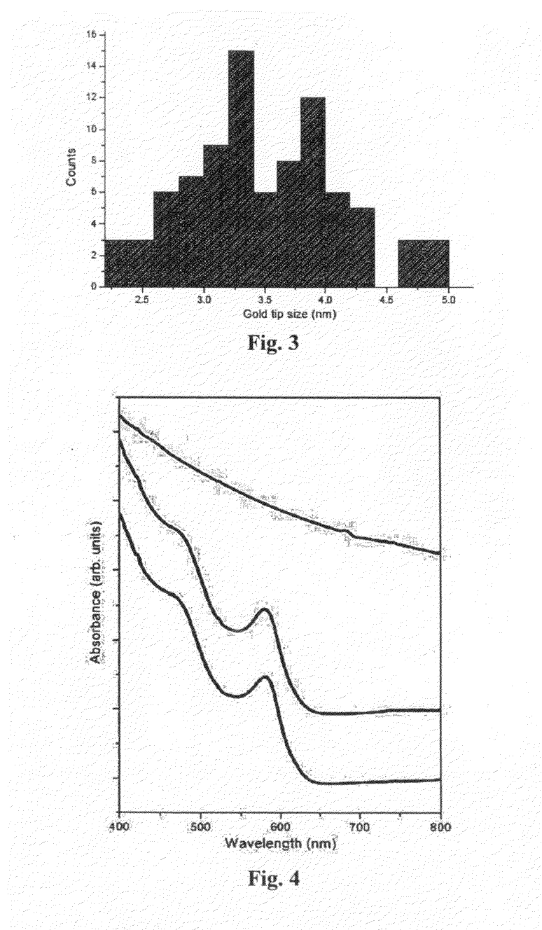

FIG. 2B shows a transmission electron microscope (TEM) image of CdSe—Au hybrid nanodumbbells prepared as described above. Selective growth of Au at both rod tips was observed, similar to what was achieved previously in organic solution. The average Au particle size was 3.5 (±0.6) nm (FIG. 3). Similar to the previous study, the growth of Au also washed out the excitonic absorption feature of the original CdSe nanorods (FIG. 4).

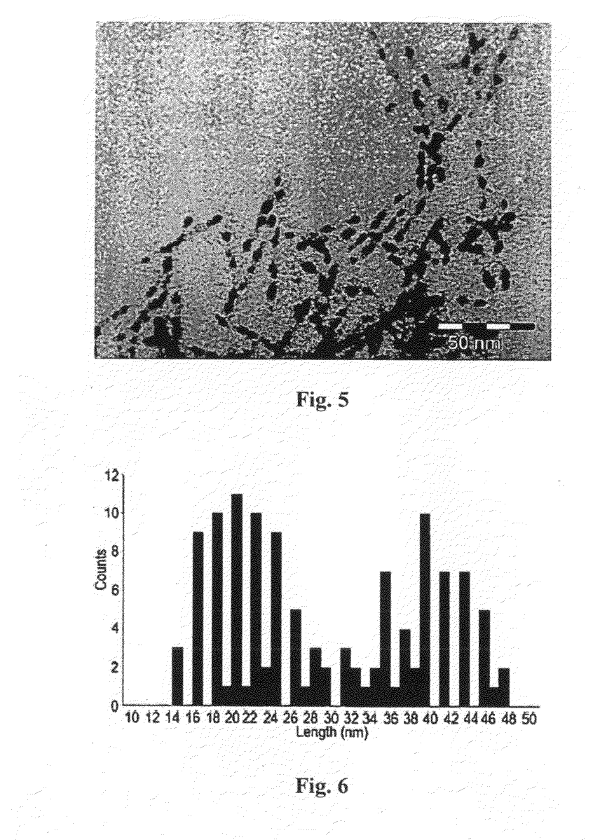

Without wishing to be bound by theory, the growth mechanism may be explained by several possible mechanisms. The first possible mechanism considered was photo-reduction of the gold by electrons generated after light absorption of the semiconductor rod. Control experiments performed under dark conditions also showed similar gold growth (FIG. 5). Closer examination of the nanodumbbells revealed significant shortening compared to the original nanorods. The average length was shortened from 38 nm for the rods in water to 22 nm in the NDBs (FIG. 6). Se²⁻ from the rods can reduce the Au³⁺ accompanied by etching of the rods which is consistent with the rod shortening.

Two types of experiments were performed to prove the charge separation and demonstrate the photocatalytic activity of the NDBs. Methylene blue (MB), a good electron acceptor with a distinctive shaped absorbance spectrum, was used as the model photo-catalyzed compound. Upon reduction by two electrons, MB is transformed to leucomethylene blue (MBH), which is transparent at the visible spectrum, providing a clear spectral signature for MB reduction.

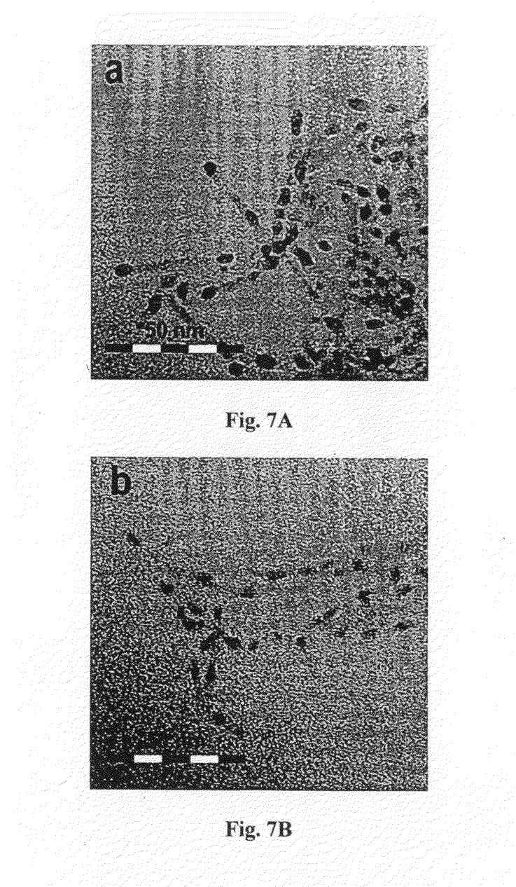

In one set of experiments, termed pre-irradiation experiments, the NDB solution was first irradiated and only then MB was added, without further illumination. Aqueous solutions (pH 7) of NDBs, with typical concentration of 5×10⁻⁸M, and ethanol as a sacrificial hole scavenger were prepared using 1:4 volume ratio of ethanol to buffer solution. Samples, prepared in a dark room, were bubbled with dry nitrogen gas in an air tight cuvette to prevent scavenging of the accumulated electrons by oxygen. Methylene blue solution was prepared by dissolving MB crystals (Sigma-Aldrich) in TDW to receive a solution with optical density of 1 at the main absorption peak of the MB at 667 nm. For each experiment, 2 ml of the NDBs aqueous solution was pre-irradiated with a CW laser at 532 nm and a power of 27 mW for variable times with stirring. This irradiation scheme was chosen so that the CdSe would effectively absorb the light at a well-defined visible wavelength, and a quantification of photons absorbed can be done. After this irradiation, 1 ml of deaerated MB dye solution was added to the cuvette. It should be noted that the NDBs did not show structural or morphological changes due to the irradiation of the sample (FIG. 7).

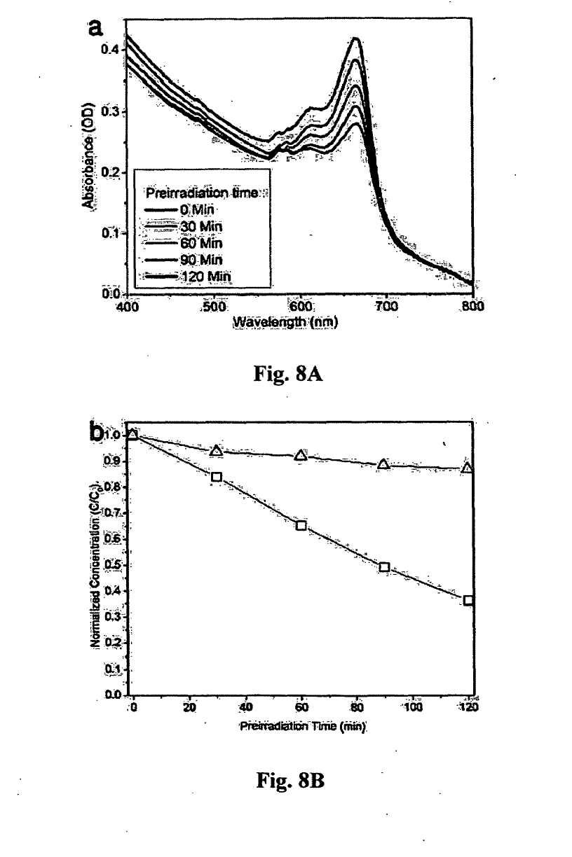

FIG. 8A shows series of absorbance spectra of MB-nanodumbbell aqueous solutions where the double peak feature of the MB (at 609 nm and at 667 nm) is clearly seen. The absorbance spectrum was acquired after letting the mixed sample stir in darkness for 30 minutes to bring the reaction to completeness as was verified by following the time trace of the absorption profile. The reduction of MB was faster than few tens of seconds, the practical limit of the measurement setup. As the NDBs reduce the MB to MBH the double peak absorbance feature diminishes as is clearly seen, and longer pre-irradiation leads to a systematic increase in the reduction, indicating more charges were retained on the NDBs. FIG. 8B plots the dependence of the reduction activity of the NDBs versus pre-irradiation time, along with the results for a control solution of a mixture of the original CdSe nanorods and Au nanoparticles of diameter 5 nm at a ratio of 1:2, and at similar concentrations to the NDB solution (triangles). The hybrid NDBs have reduced 64% of the MB dye after being pre-irradiated for 120 minutes while, for the exact same conditions, the mixture has shown only 13% reduction of the MB dye.

Additional control experiments showed that solutions of CdSe nanorods or of gold nanoparticles did not exhibit any photocatalytic reduction effects after being pre-irradiated, and hence show no charge-retention. It can therefore be concluded that the NDBs exhibit a charge separation under visible illumination consistent with the photoluminescence quenching observed previously; moreover the NDBs have the ability to retain their excited charge separated state for long times even after the illumination was switched off, if a hole scavenger is used to remove the positive charges. The NDBs, with the charge retention, can then transfer their electron to an electron acceptor in a redox reaction without the presence of light.

In the case of the CdSe nanorods and gold nanoparticles mixture the charge was retained on the gold nanoparticles in the solution and was transferred through a productive collision from an excited CdSe nanorod. Using the Stokes-Einstein relations the average collision time between the gold nanoparticles and the CdSe nanorods was estimated at approximately 1 msec which is significantly longer than the lifetime of the exciton in the CdSe nanorod (˜10 nsec). However, the presence of ethanol as a hole scavenger at a significant volume fraction in the irradiated solution allowed for hole transfer from the excited CdSe nanorod leaving a negatively charged rod that transferred its excess electron to a gold nanoparticle during a collision. In the case of NDBs, the much more effective retention of charge on the gold was assigned to the rapid charge separation between the CdSe and gold parts, accompanied by the hole scavenging by the ethanol which prevented recombination of charge carriers. The careful design of the photocatalyst therefore enabled significantly more effective activity.

The number of retained electrons per NDB can be roughly estimated from the amount of reduced MB and estimation of the NDB amount using the absorbance spectra. This yields an average retention of about 50 electrons per NDB at the longest pre-irradiation times studied.

It is also possible to use the NDBs for direct photocatalysis of the MB reduction. In a second set of experiments, termed simultaneous irradiation, the absorption (at 667 nm) of MB in a MB-nanodumbbell aqueous solution was followed while irradiating the sample with a 473 nm 30 mW CW laser. This wavelength was chosen since the MB has minimal absorbance in this range, minimizing its direct photobleaching. Samples were prepared as described hereinabove, with ethanol as a hole acceptor and MB added.

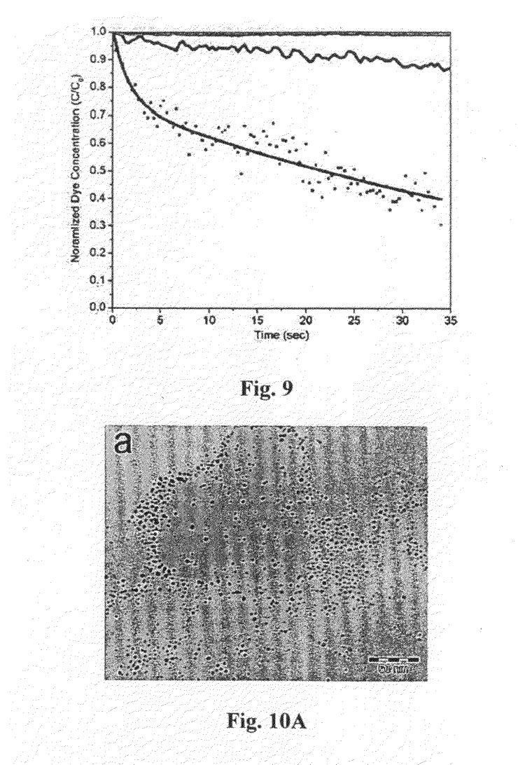

In FIG. 9, a normalized time trace of the absorbance of irradiated MB-nanodumbbell solution, MB—CdSe nanorods control solution and of MB-gold nanoparticles control solutions, where MUA coated Au particles of either 4(±0.3) nm and of 6(±1) nm in diameter were used are shown (FIG. 10 and preparation information in supporting information). After 30 minutes of irradiation the MB-nanodumbbell solution exhibited reduction of 61% of the MB dye. Control Au solutions hardly exhibited any reduction of the MB for both 4 and 6 nm particles, whereas the control CdSe nanorods solution exhibited reduction of 15% of the MB. In another control experiment only MB solution was used to estimate the amount of photobleaching of the dye under the irradiation. After 30 minutes of irradiation only about 5% of the dye has undergone photobleaching. The large decrease of MB dye absorption in the MB-nanodumbbell solution can therefore be attributed to a photocatalytic effect that occurs due to the presence of the NDBs.

These results demonstrate the use of visible light to activate a photoreduction reaction in a well defined hybrid nanostructure, as well as the possibility of retaining the charge for later use in reduction reactions, even after the irradiation is shut off. Most previous nano-photocatalyst systems used UV irradiation that could have caused direct photo-bleaching of the probe molecule, and more importantly, the semiconductor could not effectively absorb the solar spectrum in the visible range. The present system provides a high degree of control over the photocatalyst properties and additional hybrid metal-semiconductor nanoparticles can be envisioned and used as photocatalysts.

For further example of the methods and materials of the patent, room temperature approaches for growing catalytic platinum onto CdSe nanorods in an aqueous solution are also described here. The chemical and physical properties of the new hybrid nanocrystals were investigated, and their photocatalytic properties were demonstrated using once again the reduction of the model acceptor MB as described above for the Au—CdSe case.

CdSe nanorods (70×8 nm) were synthesized as disclosed. After synthesis, they were transferred to an aqueous solution by exchanging the allyl-phosphine surface ligands with mercapto-undecanoic acid (MUA). For platinum growth, PtCl₄ was dissolved in water and mixed vigorously with the CdSe nanorods aqueous solution at room temperature for 2 days. A dark brown/black precipitate was formed and collected by centrifugation to yield the CdSe—Pt hybrid particles. The separated nanocrystals were dried and re-dissolved in triple distilled water (TDW) for characterization and use in photocatalysis.

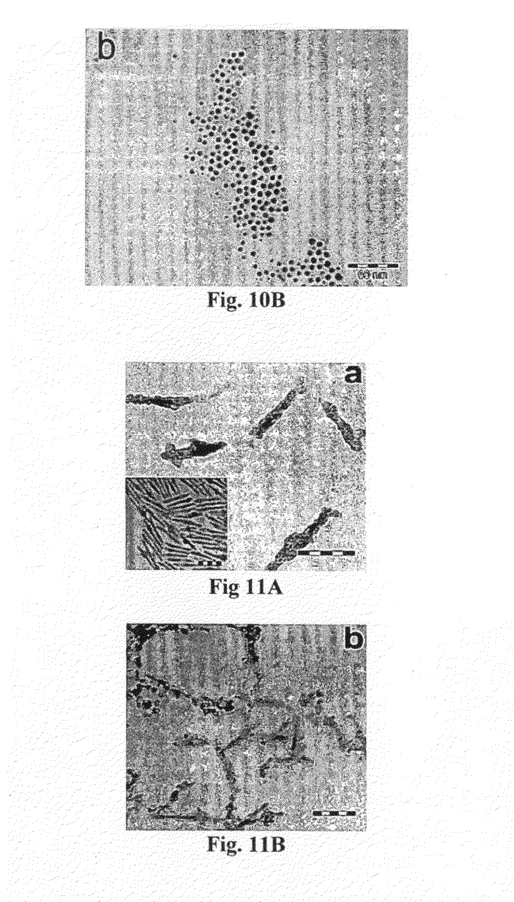

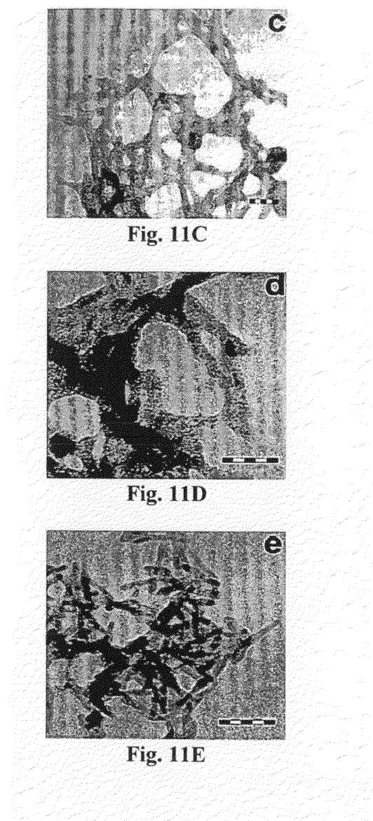

As FIG. 11 illustrates, certain changes in the growth behavior of Pt onto CdSe nanorods at different pH may be observed. In reactions under basic conditions (pH 10), metal growth occurs on the rod surface. TEM observations indicated that no fusion or aggregation had occurred in solution during growth and the rods remained separated (FIG. 11A). At pH 7 significant nanorod fusion was not observed, although clustering of the nanorods could be observed on the TEM grid (FIG. 11B), consistent with strong attractive forces are present between the hybrid nanocrystals in solution. At pH 4, Pt growth also occurred on the nanorod surface; simultaneously during growth, the nanorods began to aggregate and fuse, forming a porous, high-surface area “nanonet” structure composed of interconnected CdSe—Pt hybrid nanostructures (FIGS. 11C-D). Reactions at strongly acidic conditions (pH 1) exhibited no Pt growth on the nanorod surface, only widespread nanorod aggregation (FIG. 11E) and presence of small unattached Pt nanocrystals surrounding the nanorod aggregates.

The difference in growth behavior at the different pH conditions can be seen in the absorbance spectrum of the hybrid nanostructures (FIG. 11F). At pH 10, the absorbance of the CdSe—Pt hybrid nanorods still shows some of the excitonic structure of the original CdSe nanorod seeds, though the first exciton peak is broadened and a tail to the red develops. Such behavior was also seen during the growth of Au nanocrystals onto CdSe nanorods and appears to be an indicator of the nucleation and growth of small metal nanocrystals. As the pH becomes more acidic, the absorption features of the CdSe—Pt nanorods are washed out and absorbance in the visible spectrum is further spread out to the red. This effect likely occurs due to the fusing of the hybrid nanocrystals to form nanonets, which leads to an increase in solution scattering due to the presence of larger colloids.

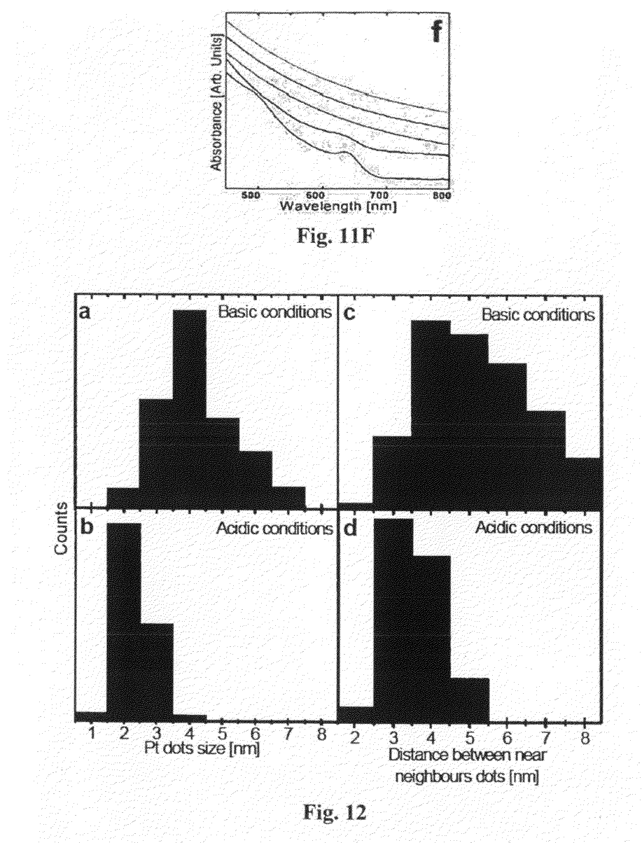

The solution pH during growth also influences the characteristics of the Pt nanocrystals grown on the CdSe nanorods. The distribution of sizes and nearest neighbor distances of over 200 Pt dots for the pH 4 and pH 10 growth conditions are presented in FIG. 12. The average diameter of the Pt dots grown under basic condition is 3.3±1.1 nm (FIG. 12A), while in acidic conditions the Pt nanocrystal size is 1.9±0.5 nm (FIG. 12B). The mean nearest neighbor distance for Pt dots grown under basic conditions is 5.3±2.0 nm (FIG. 12C), nearly twice as large in comparison to the distance for Pt dots grown under acidic condition, 3.1±0.7 nm (FIG. 12D).

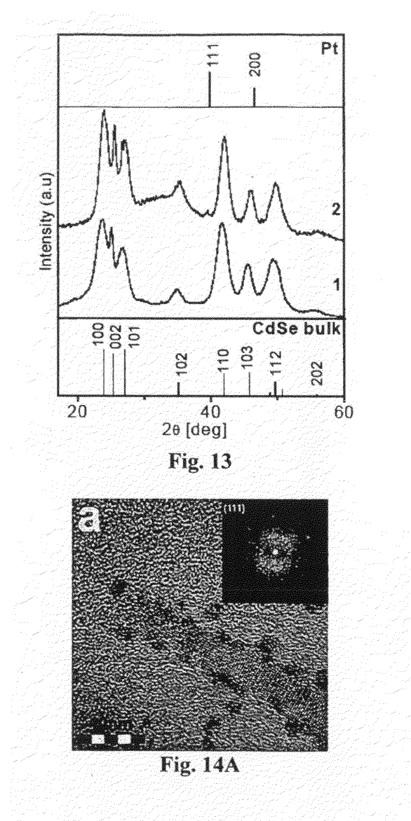

The structure and chemical composition of the CdSe—Pt hybrid nanocrystals were studied. Energy Dispersive X-ray (EDX) spectra (not shown) taken in HRTEM for CdSe—Pt hybrid particle prepared at pH 4, over a ˜1 μm area, showed the expected Cd, Se and Pt peaks. The Cd:Se atomic ratio was 1:1.07, close to the expected 1:1 ratio in CdSe nanorods. The ratio between CdSe and Pt was approximately 2.4:1. The Powder X-ray Diffraction (XRD) for CdSe nanorods with dimensions of 70×8 nm before and after Pt growth (at pH 10) is shown in FIG. 13. The appearance of the small Pt (111) peak after Pt growth provides additional evidence that crystalline Pt is present. Given the small Pt particle size, a broad and weak peak can be expected.

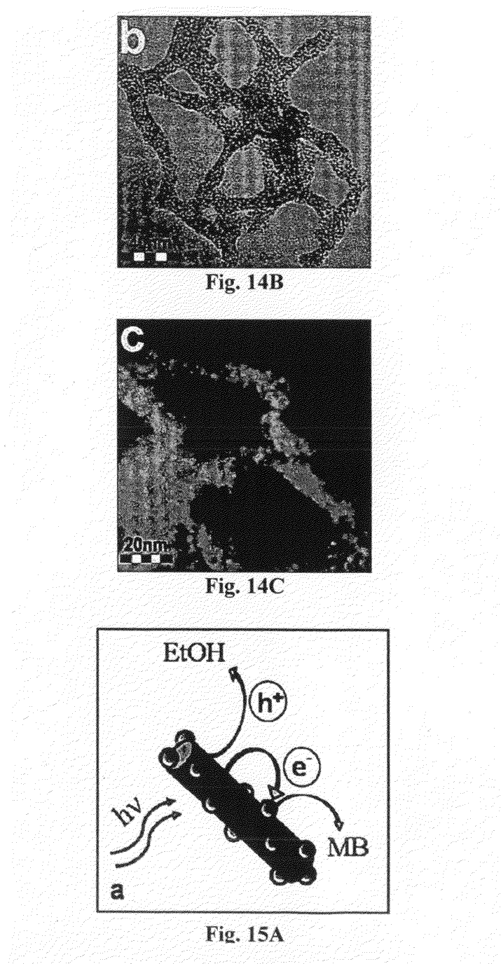

To confirm that Pt is directly attached to the nanorod surface, High Resolution TEM (HRTEM) and High Angle Annular Dark Field Scanning TEM imaging (HAADF-STEM) techniques were used. FIG. 14A shows an image of a single CdSe—Pt nanorod grown at pH 10. The CdSe (002) lattice of the rod can be well identified, but the Pt dots are very small (average diameter of 3.3±1.1 nm) complicating direct observation of their lattice structure. The fast Fourier transform (FFT) of selected nanocrystals in the TEM micrograph was calculated and used to identify lattice structures which were difficult to resolve clearly by eye (inset of FIG. 14A). The (111) plane of Pt nanocrystals was determined. FIGS. 14B-C show HRTEM and HAADF-STEM characterization of Pt growth at pH 4; as discussed above, under these conditions the nanorods tend to fuse and form a nanonet during Pt growth. The bright white dots in the HAADF-STEM (FIG. 14C) are the platinum dots on the surface of the gray nanorods, as this method provides atomic number contrast (Z-contrast imaging) where the heavier Pt atoms scatter strongly.

The function of the CdSe—Pt hybrid nanoparticles in visible light photocatalysis is next demonstrated. As mentioned above, the utility of metal-semiconductor hybrid nanostructure for photocatalysis relies on the charge separation at the metal/semiconductor interface, which can effectively compete with rapid electron-hole recombination in the semiconductor. Visible light photocatalysis and charge retention were observed in CdSe—Au nanodumbbells (NDBs) described above, and the same was extended to the CdSe—Pt systems.

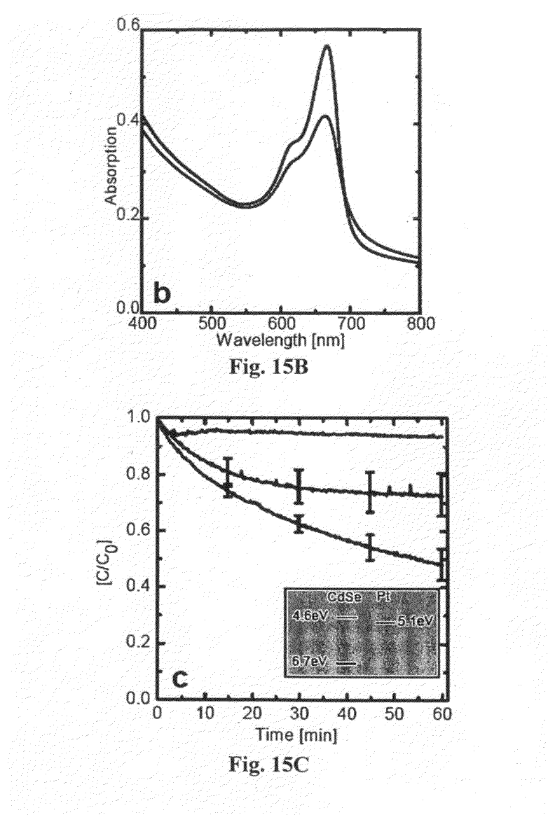

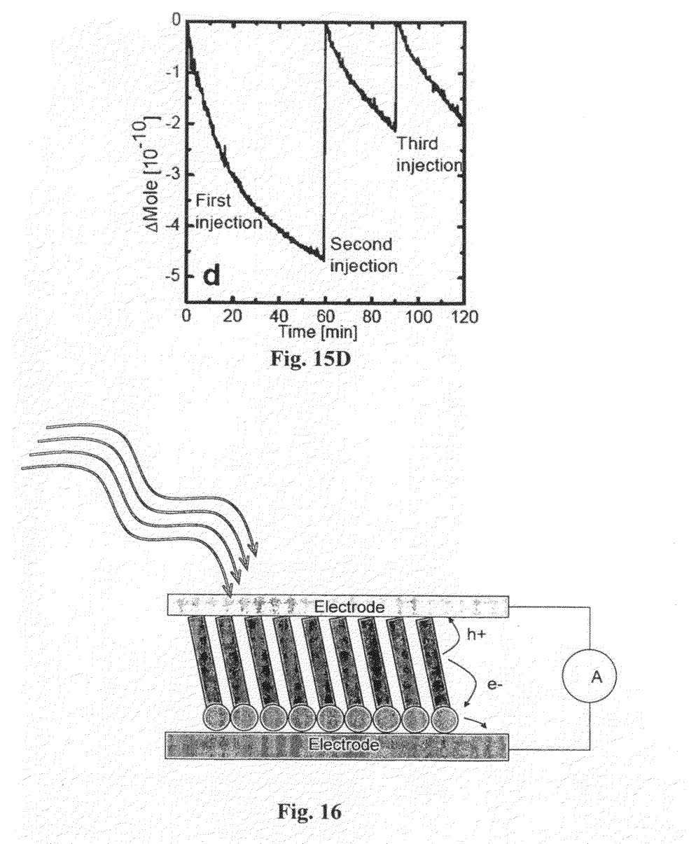

To this end, as before, MB was used as an electron acceptor and ethanol as a hole scavenger. The suggested scheme for the charge separation and the redox reaction is illustrated in FIG. 15A; after irradiation of the sample and formation of photo-induced charge carriers in the hybrid particle, the electron and hole relax to the lowest energy levels in the system with the electron residing in the platinum dot and the hole in the CdSe nanorod. In this state, by way of example, the hole may be transferred to the ethanol and the electron to the MB. Upon the addition of two electrons, MB is reduced to form colorless leucomethylene blue (MBH).

To follow the photocatalysis of MB reduction, the decrease of the main absorption peak of MB (667 nm) was monitored over time, while continuously irradiating the sample with a 473 nm 30 mW CW blue laser so that only the nanorods undergo excitation (and not the MB dye directly). Samples of CdSe—Pt were re-dispersed using 1:4 volume ratio of ethanol to water, and the pH of these solutions was set to 7 using a buffer. The samples were then deaerated by bubbling dry nitrogen gas for several minutes in an airtight cuvette, followed by the addition of MB dissolved in water. FIG. 15B shows the absorbance of the solution at time 0, and after 60 minutes of irradiation. The decrease of MB main peak indicated considerable reduction. FIG. 15C shows a normalized time trace (C/Co, where Co is the MB concentration at time 0) of the absorbance of the samples at 667 nm, the main absorbance peak of MB. These plots display the average results of several different experiments with similar properties.

The photocatalysis activity of CdSe—Pt grown at basic (nanorods) and acidic (nanonets) conditions was compared. After 60 minutes of irradiation the MB/CdSe—Pt nanonets (FIG. 15C) exhibited reduction of 46% of the MB dye and the MB/CdSe—Pt isolated nanorods exhibited 25% of the MB. Irradiation of a solution containing MB and ethanol without particles showed only 2% direct photobleaching. Adding CdSe nanorods to the mixture yielded only 10% reduction. Pt dots (2 nm, grown in toluene and transferred to water with MUA) showed 4% reduction. A mixture of CdSe nanorods with Pt dots at ratio of 1:20 (to reflect the ratio in the Pt—CdSe nanorods) showed 5% reduction of MB. Clearly the CdSe—Pt hybrid show significant photocatalysis activity. This is assigned to the charge separation taking place at the metal semiconductor interface followed by hole scavenging by ethanol and reduction of MB. Pt is known to be an effective catalyst metal.

Moreover, improved photocatalysis activity was observed in nanonets compared to nanorods. This is consistent with the smaller mean size of the Pt dots at acidic pH which may lead to enhanced reactivity. Furthermore, at the acidic conditions the rod surface coverage with Pt dots is denser than in the basic conditions, providing more catalytic sites on the CdSe—Pt nanonets in comparison to the CdSe—Pt nanorods. Without being limited by theory, charge separation may therefore also be more effective in the nanonets.

To further show the photocatalysis effect for CdSe—Pt hybrids, the irradiation was continued after 60 minutes while adding further MB amounts in two injections, each one consisted half of the original MB amount. This was done on a sample of CdSe—Pt nanonets prepared at pH 4. As can be seen in FIG. 15D, the system still keeps reducing the dye upon additional injections showing that the activity remains similar.

The methods of the invention may be carried out in an electrochemical cell comprising a plurality of nanoparticles being free in solution or deposited as a layer on the surface of an electrode. In one exemplary and general set up, shown for the sake of illustration in FIG. 16 a photovoltaic cell is constructed of a self-assembled layer of nanoparticles placed between the electrodes of the cell. In this example, one electrode is ITO or a transparent electrode through which light can enter the cell. In this set up, the different regions of each of the nanoparticles are in contact with the different electrodes of the cell. Following light absorption, charge separation takes place.

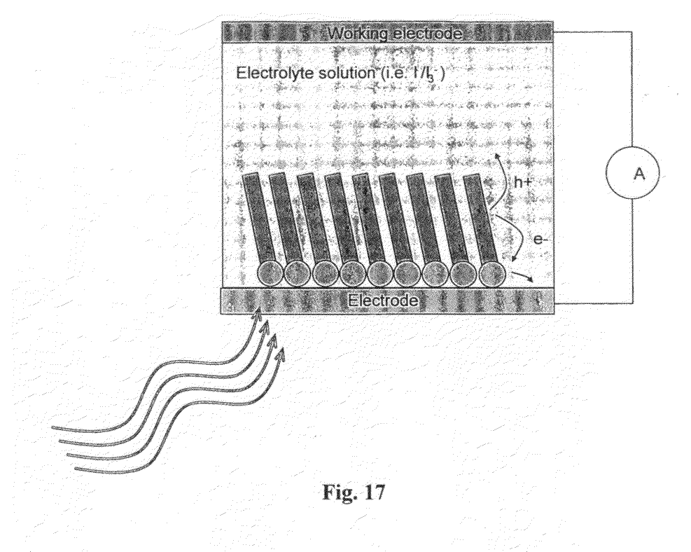

Similarly to the photovoltaic cell, a photoelectrochemical cell of the exemplary construction shown in FIG. 17 may be constructed. As shown, instead of arranging the nanoparticles to a contact with each of the electrodes, the electrolyte solution is used as an intermediate, typically with the metal region of each of the nanoparticles being in contact with one of the electrodes. A redox reaction takes place in an aqueous medium allowing charges to move from the nanoparticles to the electrode, thereby producing electrical current.

As a person skilled in the art will appreciate, the examples provided herein are only certain specific embodiments of the invention. Other embodiments of the nanoparticles, methods, uses and devices may be constructed which fall within the scope of the invention disclosed and claimed.

1-67. (canceled)

68. A method of photo-inducing charge separation and transfer of a charge carrier to a charge acceptor, the method comprising:
providing at least one nanoparticle comprising at least one metal/metal alloy region and at least one semiconductor region, having an absorption onset in the visible (400-700 nm) to near infrared (NIR) range (0.7-3 μm);
contacting the at least one nanoparticle with at least one electron acceptor and at least one electron donor in a medium selected from a liquid medium, a gel, or a solid medium, wherein a plurality of the at least one nanoparticles is freely-distributed in the medium; and
optionally, irradiating the medium containing the at least one nanoparticle, at least one electron acceptor and at least one electron donor with radiation in the visible and/or near IR range and optionally UV range;
thereby allowing formation of an electron-hole pair in the metal/semiconductor interface of the at least one nanoparticle and subsequent charge separation and transfer of the electron and hole to the at least one electron acceptor and the at least one electron donor, respectively,
the at least one nanoparticle having an elongated shape, a rod-like shape, an elliptical shape, a pyramidal shape or a disk-like shape.

69. The method according to claim 68, wherein the at least one nanoparticle comprises at least two metal/metal alloy regions, separated by at least one semiconductor region, wherein each of the at least two metal/metal alloy regions is of a different or same metal/metal alloy material.

70. The method according to claim 68, wherein the at least one nanoparticle comprises at least two metal/metal alloy regions, separated by at least two semiconductor regions, wherein each of the at least two metal/metal alloy regions is of a different or same metal/metal alloy material and each of the at least two semiconductor regions have a different energy gap and/or different energy band positions.

71. The method according to claim 70, wherein the at least two semiconductor regions are separated by at least one metal/metal alloy region.

72. The method according to claim 71, wherein each of the at least two semiconductor regions is of a different semiconducting material, the regions being not separated by a metal/metal alloy region.

73. The method according to claim 68, wherein the at least one nanoparticle is a nanorod or a nanodumbbell, NDB.

74. The method according to claim 73, wherein the NDB has at one of its ends a first metal/metal alloy region and on the other of its ends a second metal/metal alloy region, the first and second metal/metal alloy regions differing from each other in their chemical composition.

75. The method according to claim 74, wherein the NDB has at least one additional metal/metal alloy region in the elongated segment of the nanostructure.

76. The method according to claim 73, wherein the at least one nanoparticle is in the form of a nanorod having on its surface at least one region of at least one metal/metal alloy material.

77. The method according to claim 76, wherein the nanorod has on its surface a plurality of spaced apart metal/metal alloy regions, of the same or different metal/metal alloy material.

78. The method according to claim 68, wherein the at least one metal/metal alloy region is of at least one metal selected from the group consisting of Cu, Ag, Au, Pt, Co, Pd, Ni, Ru, Rh, Mn, Cr, Fe, Ti, Zn, Ir, W, Mo, and alloys thereof.

79. The method according to claim 68, wherein the at least one semiconductor region is of a semiconducting material selected from elements of Group II-VI, Group III-V, Group IV-VI, Group III-VI, Group IV semiconductors and combinations thereof.

80. The method according to claim 79, wherein the metal is selected from the group consisting of Au, Pd, Pt, and alloys thereof.

81. The method according to claim 79, wherein the at least one semiconductor is of Group II-VI and is selected from the group consisting of CdSe, CdS, CdTe, ZnSe, ZnS, ZnTe, HgS, HgSe, HgTe, CdZnSe, and alloys thereof.

82. The method according to claim 79, wherein the at least one semiconductor is of Group III-V and is selected from the group consisting of InAs, InP, GaAs, GaP, InN, GaN, InSb, GaSb, AlP, AlAs, AlSb, InAsP, CdSeTe, ZnCdSe, InGaAs, and alloys thereof.

83. The method according to claim 79, wherein the at least one semiconductor is of Group IV-VI and is selected from the group consisting of PbSe, PbTe, PbS, and alloys thereof.

84. The method according to claim 79, wherein the at least one semiconductor is of Group III-VI and is selected from the group consisting of InSe, InTe, InS, GaSe, InGaSe, InSeS, and alloys thereof.

85. The method according to claim 79, wherein the at least one semiconductor is of Group IV and is selected from the group consisting of Si, Ge, and alloys thereof.

86. The method according to claim 68, wherein the at least one semiconductor region is of CdS, CdSe or CdTe and the at least one metal/metal alloy region is of Au, Pt, Pd, or alloys thereof.

87. The method according to claim 68, wherein the radiation is solar radiation.

88. A method for reducing at least one first organic or inorganic compound, and/or oxidizing at least one second organic or inorganic compound, the method comprising:
providing at least one nanoparticle comprising at least one metal/metal alloy region and at least one semiconductor region;
contacting the at least one nanoparticle with the at least one first organic or inorganic compound being an electron acceptor and at least one second organic or inorganic compound being an electron donor in a medium; and
optionally, irradiating the medium with radiation in the visible and/or near IR range and optionally UV range;
thereby allowing reduction of the at least one first organic or inorganic compound and/or oxidation of the at least one second organic or inorganic compound,
the at least one nanoparticles having an elongated shape, a rod-like shape, an elliptical shape, a pyramidal shape or a disk-like shape.

89. A method for the photocatalytic production of hydrogen, the method comprising irradiating an aqueous medium comprising at least one nanoparticle having at least one metal/metal alloy region and at least one semiconductor region and a shape selected from an elongated shape, a rod-like shape, an elliptical shape, a pyramidal shape and a disk-like shape, with light in the visible and/or near IR range and optionally UV range to obtain hydrogen following water splitting.

90. The method according to claim 89, wherein the light is solar light.

91. The method according to claim 89, wherein the aqueous medium is water.

92. The method according to claim 89, wherein the aqueous medium is a medium comprising water.
